(19) United States
(12) Patent Application Publication
(10) Pub. No.: US 2005/0106875 A1
(43) Pub. Date: May 19, 2005

(54) Plasma ashing method

(75) Inventors: Kazuhiro Kubota, Nirasaki-shi (JP); Yoshiki Igarashi, Nirasaki-shi (JP); Shigeru Tahara, Nirasaki-shi (JP); Shin Okamoto, Nirasaki-shi (JP); Toshihiko Shindo, Nirasaki-shi (JP); Yoshinobu Ooya, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/948,241

(22) Filed: Sep. 24, 2004

(30) Foreign Application Priority Data
Sep. 25, 2003 (JP) 2003-333315

(51) Int. Cl. H01L 21/302; H01L 21/306; H01L 21/461

(52) U.S. Cl. 438/689

(57) ABSTRACT

A plasma ashing method of an object to be processed removes a resist film therefrom in a processing vessel after etching a part of a low dielectric constant film with the resist film having a pattern thereon as a mask in the processing vessel. The plasma ashing method includes a first and a second ashing processes. The first ashing process removes deposits off an inner wall of the processing vessel by using a first processing gas including at least O₂ gas while controlling the pressure in the processing vessel to be smaller than or equal to 20 mTorr. The second ashing process removes the resist film by using a second processing gas including at least O₂ gas.

### FIELD OF THE INVENTION

The present invention relates to a plasma ashing method.

### BACKGROUND OF THE INVENTION

In a conventional semiconductor manufacturing process, a resist film formed on an object to be processed such as a semiconductor wafer (hereinafter, referred to as ‘wafer’) or the like is normally removed by employing a plasma ashing method wherein the wafer is heated in a processing vessel and, at the same time, O₂ gas is introduced into the processing vessel to thereby remove the resist film by using such active species as O radicals generated when the O₂ gas is plasmatized.

By performing a plasma etching process and a plasma ashing process successively in the same processing vessel, the time required to transfer the object to be processed to another processing vessel can be saved, thereby entailing a reduction in the overall processing time.

However, if the plasma etching process is performed by using a processing gas including a fluorine gas, for example, a fluorine polymer, may be deposited on an inner wall of the processing vessel. If the ashing process is continued in such a manner, the fluorine polymer deposited on the inner wall of the processing vessel can be redissociated, resulting in a memory effect in which a film on the object to be processed is etched. The memory effect may lower the performance of a semiconductor.

In order to prevent the memory effect from occurring, a method of carrying out the ashing process in two steps has been conventionally employed. As the first step, plasma is generated in the processing vessel without applying a bias voltage to the object to be processed and, accordingly, the fluorine polymer deposited on the inner wall of the processing vessel is removed. As the second step, the bias voltage is applied to the object to be processed, and the resist film on the object to be processed is removed. Such process of removing the resist film in two steps is referred to as ‘hybrid-ashing’. The hybrid-ashing is disclosed in Japanese Patent Laid-open Application Nos. H11-145111, 2000-183040, H6-45292, H10-209118 and 2001-176859.

If, however, the object to be processed contains a low dielectric constant film (a low-k film) and, especially, if the low-k film is exposed thereto, the hybrid-ashing can inflict damages on the low-k film. Specifically, the O radicals generated in the processing vessel during the ashing method may deteriorate the low-k film, thereby increasing the dielectric constant (k value) of the low-k film. Further, when the fluorine polymer deposited on the inner wall of the processing vessel is removed in the first step of the hybrid-ashing, there is a possibility that a part of the fluorine is redissociated to penetrate into the low-k film. In that case, the dielectric constant of the low-k film may also increase.

If the dielectric constant of the low-k film increases, the electrostatic capacitance between Cu wirings insulated by the low-k film increases, thereby deteriorating the transfer speed of a signal. Such phenomenon may lead to a reduction in the operating speed of a semiconductor device.

Further, if the conventional hybrid-ashing is performed on an object to be processed which contains the low-k film, there is a possibility of inflicting damages onto an under film, e.g., an etching stop film, of the low-k film. To be specific, the under film may be etched and damaged during an ashing of the resist film.

### SUMMARY OF THE INVENTION

The present invention has been developed to rectify the aforementioned drawbacks. Accordingly, an object of the present invention is to provide a new and improved plasma ashing method capable of efficiently removing a resist film from an object to be processed without damaging a low dielectric constant film of the object to be processed and an under film of the low dielectric constant film.

In accordance with a preferred embodiment of the present invention, there is provided a plasma ashing method of an object to be processed for removing a resist film therefrom in a processing vessel after etching a part of a low dielectric constant film with the resist film having a pattern thereon as a mask in the processing vessel, the plasma ashing method including the steps of: a first ashing process for removing deposits off an inner wall of the processing vessel by using a first processing gas including at least O₂ gas while controlling the pressure in the processing vessel to be smaller than or equal to 20 mTorr; and a second ashing process for removing the resist film by using a second processing gas including at least O₂ gas. In accordance with this method, the deposits are removed from the inner wall of the processing vessel during the first ashing process and, thus, the object to be processed, especially, the low dielectric constant film therein can be free of damages which may be caused by redissociated deposits during the following second ashing process. Further, in the first ashing process, by keeping the pressure in the processing vessel not higher than 20 mTorr (about 2.67 Pa), the O radical density in the processing vessel can be lowered. Consequently, it is possible to prevent deterioration of the quality of the low dielectric constant film.

Moreover, by keeping the pressure in the processing vessel not higher than 20 mTorr during the second ashing process, the O radical density in the processing vessel is lowered, and the quality of the low dielectric constant film can be maintained at a satisfactory state.

The first processing gas preferably includes at least O₂ gas and a first unreactive gas, e.g., Ar gas, N₂ gas, He gas or Xe gas. Accordingly, in the first ashing process, generation of O radicals in the processing vessel can be suppressed. Further, if the flow rate of the first unreactive gas included in the first processing gas is controlled to occupy 50 to 90% of the total flow rate of the O₂ gas and the first unreactive gas, generation of O radicals in the first ashing process can be further suppressed.

In the second ashing process, in order to suppress the generation of O radicals in the processing vessel, the second processing gas preferably includes at least O₂ gas and a second unreactive gas, e.g., Ar gas, N₂ gas, He gas or Xe gas. Further, if the flow rate of the second unreactive gas included in the second processing gas is controlled to occupy 50 to 90% of the total flow rate of the O₂ gas and the second unreactive gas, generation of the O radicals in the second ashing process can be further suppressed.

In accordance with another preferred embodiment of the present invention, there is provided a plasma ashing method of an object to be processed for removing a resist film therefrom in a processing vessel after etching a part of a low dielectric constant film with the resist film having a pattern thereon as a mask in the processing vessel, the plasma ashing method including the steps of: a first ashing process for removing deposits off an inner wall of the processing vessel by using a first processing gas including at least O₂ gas and a first unreactive gas; and a second ashing process for removing the resist film by using a second processing gas including at least O₂ gas and a second unreactive gas. In accordance with this method, the deposits are removed from the inner wall of the processing vessel during the first ashing process and, thus, the object to be processed, especially, the low dielectric constant film therein can be free of damages which may be caused by redissociated deposits in the following second ashing process. Further, since the first processing gas including at least the O₂ gas and the first unreactive gas, and the second processing gas including at least the O₂ gas and the second unreactive gas are used in the first and the second ashing processes, respectively, the O radical density in the processing vessel during the first and the second ashing processes becomes low. As a result, deterioration of the quality of the low dielectric constant film can be prevented.

In the first ashing process, it is preferable that either no electric power is applied to the object to be processed or the electric power applied thereto is smaller than or equal to 0.19 W/cm². Accordingly, the deposits can be removed from the inner wall of the processing vessel without inflicting damages on the object to be processed. On the other hand, in the second ashing process, it is preferable to apply electric power greater than or equal to 0.19 W/cm² to the object to be processed, so that the resist film can be removed at a relatively high ashing rate while maintaining a satisfactory quality of the low dielectric constant film.

In accordance with a further preferred embodiment of the present invention, there is provided a plasma ashing method of an object to be processed for removing a resist film therefrom in a processing vessel after etching a part of a low dielectric constant film with the resist film having a pattern thereon as a mask in the processing vessel, the plasma ashing method including the step of: an ashing process for removing the resist film by using a processing gas including at least O₂ gas while controlling the pressure in a processing chamber to be smaller than or equal to 20 mTorr. In accordance with such method, the resist film can be removed without inflicting damages on the low dielectric constant film which is made of a material containing, e.g., Si, O, C and H, and an under film thereof. Especially, if the pressure in the processing chamber is controlled within the range of 3 to 20 mTorr, the effects can be enhanced.

The processing gas can be the O₂ gas alone or a gaseous mixture of O₂ gas and an unreactive gas. Regardless of the processing gas used, however, damages to the under film of the low dielectric constant film and deterioration in the quality of the low dielectric constant film during the ashing process can be prevented. The flow rate of the unreactive gas included in the processing gas preferably occupies 75 to 87.5% of the total flow rate of the O₂ gas and the unreactive gas. Furthermore, it is preferable to employ He gas or Ar gas as the unreactive gas, because of their availability and their ability to protect the low dielectric constant film and the under film thereof. The ashing process on the resist film is preferably performed by a first ashing process followed by a second ashing process. Moreover, if the processing apparatus used in the ashing process has a structure wherein a first electric power having a first frequency of, e.g. 100 MHz, and a second electric power having a second frequency of, e.g., 3.2 MHz, which is smaller than the first frequency, can be simultaneously applied to an electrode for mounting thereon an object to be processed, it is preferable to apply at least the first electric power which is adjusted to a first electric power level, to the electrode during the first ashing process; and during the second ashing process, at least the first electric power adjusted to a second electric power level, which is higher than the first electric power level, to the electrode. By employing such method, it is possible to suppress damages to the low dielectric constant film and the under film thereof during the conventional ashing process.

It is preferable that an electric power of 0.18 to 0.44 W/cm² is applied to the electrode from the first electric power adjusted to the first electric power level and that of 0.88 to 2.20 W/cm² is applied thereto from the first electric power adjusted to the second electric power level.

In the first and the second ashing processes, the second electric power does not have to be applied to the electrode. In this case, only the first electric power is applied to the electrode in the first and the second ashing processes.

In addition, the second electric power (e.g., smaller than or equal to 0.44 W/cm²) can be applied to the electrode during the second ashing process without applying the second electric power thereto during the first ashing process.

Moreover, the second electric power (smaller than or equal to 0.18 W/cm²) adjusted to a third power level can be applied to the electrode during the first ashing process, and the second electric power (smaller than or equal to 0.44 W/cm²) adjusted to a fourth electric power level, being higher than the third electric power level can be applied to the electrode during the second ashing process.

It is preferable to control the flow rate of the processing gas in the first and the second ashing processes independently. For example, the flow rate of the processing gas is controlled to range from 100 to 800 sccm in the first ashing process, and that in the second ashing process is independently controlled to range from 100 to 800 sccm.

### BRIEF DESCRIPTION OF THE DRAWINGS

The above and other objects and features of the present invention will become apparent from the following description of preferred embodiments, given in conjunction with the accompanying drawings, in which:

FIG. 1 shows a schematic diagram of a plasma processing apparatus in accordance with a first preferred embodiment of the present invention;

FIG. 2 illustrates a schematic sectional view depicting a film structure of a first object to be processed on which an etching process and an ashing process are performed by the plasma processing apparatus shown in FIG. 1;

FIG. 3 describes a schematic sectional view illustrating a film structure of a second object to be processed on which an etching process and an ashing process are performed by the plasma processing apparatus shown in FIG. 1;

FIG. 4 provides an explanatory diagram of a method for judging the degree of damage of a low-k film;

FIG. 5 presents a graph depicting a relationship between an in-chamber pressure and a CD shift in a first ashing process;

FIG. 6 represents a graph showing a relationship between processing gas species and the CD shift in the first ashing process;

FIG. 7 depicts a graph illustrating a relationship between a processing gas flow rate ratio and the CD shift in the first ashing process;

FIG. 8 offers a graph showing a relationship between the in-chamber pressure and an O radical density in the first ashing process;

FIG. 9 sets forth a graph describing a relationship between the in-chamber pressure and an ion incidence amount in the first ashing process;

FIG. 10 describes a graph showing a relationship between the in-chamber pressure and a sheath voltage of a chamber wall in the first ashing process;

FIG. 11 depicts a graph illustrating a relationship between the in-chamber pressure and a sheath voltage on a wafer in the first ashing process;

FIG. 12 presents a graph depicting a relationship between an Ar gas flow rate and the O radical density in the first ashing process;

FIG. 13 represents a graph describing a relationship between the Ar gas flow rate and the ion incidence amount in the first ashing process;

FIG. 14 provides a graph presenting a relationship between the Ar gas flow rate and the sheath voltage of the chamber wall in the first ashing process;

FIG. 15 illustrates a graph showing a relationship between the Ar gas flow rate and the sheath voltage on the wafer in the first ashing process;

FIG. 16 is a graph showing a relationship between a lower electrode electric power and a CD shift in a second ashing process;

FIG. 17 shows a graph illustrating a relationship between an upper/lower electrode gap and the CD shift in the second ashing process;

FIG. 18 presents a graph representing a relationship between an in-chamber pressure and the CD shift in the second ashing process;

FIG. 19 represents a graph depicting a relationship between processing gas species and the CD shift in the second ashing process;

FIG. 20 provides a graph showing a relationship between a processing gas flow rate ratio and the CD shift in the second ashing process;

FIG. 21 depicts a graph describing a relationship between the processing gas flow rate ratio and the CD shift in the first and the second ashing processes;

FIG. 22 describes a graph illustrating a relationship between an upper electrode electric power and the CD shift in the first and the second ashing processes;

FIG. 23 offers a graph presenting a relationship between a processing gas flow rate and the CD shift in the first and the second ashing processes;

FIG. 24 sets forth a graph showing a relationship between the lower electrode electric power and a bias voltage applied to an object to be processed in the second ashing process;

FIG. 25 is a graph representing a relationship between the lower electrode electric power and the O radical density in the second ashing process;

FIG. 26 provides a graph illustrating a relationship between the upper electrode electric power and an ion incidence amount in the second ashing process;

FIG. 27 depicts a graph explaining a relationship between the upper electrode electric power and the O radical density in the second ashing process;.

FIG. 28 illustrates a graph showing a relationship between the in-chamber pressure and the ion incidence amount in the second ashing process;

FIG. 29 is a graph depicting a relationship between the in-chamber pressure and the O radical density in the second ashing process;

FIG. 30 sets forth a schematic diagram of a plasma processing apparatus in accordance with a second preferred embodiment of the present invention;

FIG. 31 represents a graph presenting a relationship between a processing gas flow rate and an in-chamber pressure; and

FIG. 32 provides a graph illustrating a relationship between the processing gas flow rate and an opening degree of a gas exhaust valve.

### DETAILED DESCRIPTION OF THE PREFERRED EMBODIMENTS

Preferred embodiments of the present invention will now be described in detail with reference to the accompanying drawings. Further, like reference numerals will be given to like parts having substantially the same functions, and redundant description thereof will be omitted in the specification and the accompanying drawings.

A. First Preferred Embodiment

A1. Plasma Processing Apparatus

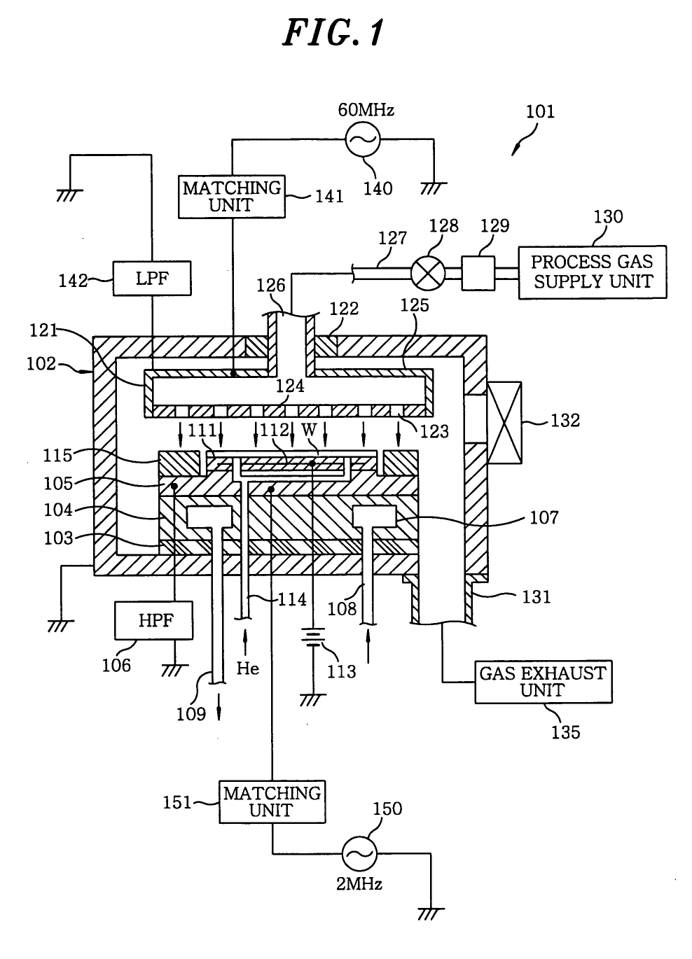

FIG. 1 shows a schematic configuration of a parallel plate plasma processing apparatus 101 as an exemplary plasma processing apparatus in accordance with a first preferred embodiment of the present invention.

The plasma processing apparatus 101 has a cylindrically shaped chamber 102 (a processing vessel) made of aluminum having an anodic oxidized (an alumite-processed) surface, wherein the chamber 101 is grounded. Provided on a bottom portion of the chamber 102 is an approximately cylindrically shaped susceptor supporting table 104 for mounting thereon a semiconductor wafer W (hereinafter, referred to as a wafer) as an object to be processed via an insulating plate 103 such as ceramic or the like. Installed on the susceptor supporting table 104 is a susceptor 105 constituting a lower electrode. A high pass filter (HPF) 106 is connected to the susceptor 105.

A temperature control medium space 107 is set inside the susceptor supporting table 104. A temperature control medium is introduced into the temperature control medium space 107 via an inlet line 108 and circulated therein. Then, the temperature control medium is discharged from a discharge line 109. By circulating the temperature control medium, the susceptor 105 can be controlled to a desired temperature.

An upper central portion of the susceptor 105 is formed in the shape of a convex circular plate, and an electrostatic chuck 111 having an approximately same shape as the wafer W is provided thereon. The electrostatic chuck 111 is formed by interposing an electrode 112 between insulators. A DC voltage of, e.g., 1.5 kV is applied from a DC electric power supply 113 connected to the electrode 112 to the electrostatic chuck 111. Accordingly, the wafer W is attached to the electrostatic chuck 111.

In order to supply a heat transfer medium, e.g., a backside gas such as He gas or the like, to the backside of the wafer W, a gas channel 114 is provided on the susceptor supporting plate 104, the susceptor 105 and the electrostatic chuck 111. Heat is transferred between the susceptor 105 and the wafer W via the heat transfer medium, and the wafer W is maintained at a predetermined temperature.

A loop-shaped focus ring 115 is set around an upper peripheral portion of the susceptor 105 to enclose the wafer W mounted on the electrostatic chuck 111. The focus ring 115 is made of an insulating material such as ceramic, quartz or the like, or a conductive material. By disposing the focus ring 115 thereon, a uniformity of etching is achieved.

Besides, an upper electrode 121 is provided above the susceptor 105 facing the susceptor 105 in a parallel way. The upper electrode 121 is supported inside the chamber 102 via an insulating member 122. Further, the upper electrode 121 includes an electrode plate 124 facing the surface of the susceptor 105 and having a plurality of injection openings 123; and an electrode supporting member 125 supporting the electrode plate 124. The electrode plate 124 is made of an insulating material or a conductive material. In this embodiment, the electrode plate 124 is made of silicon. The electrode supporting member 125 is made of a conductive material such as aluminum having an alumite-processed surface or the like. A gap between the susceptor 105 and the upper electrode 121 is controllable.

A gas inlet opening 126 is provided at a central portion of the electrode supporting member 125 in the upper electrode 121. A gas supply line 127 is connected to the gas inlet opening 126. Further, a processing gas supply source 130 is connected to the gas supply line 127 via a valve 128 and a mass flow controller 129.

An etching gas for plasma etching is supplied from the processing gas supply source 130. Although FIG. 1 shows a single processing gas supply system including the gas supply line 127, the valve 128, the mass flow controller 129, the processing gas supply source 130 and the like, the plasma processing apparatus 101 may have a plurality of processing gas supply systems. Thus, the flow rates of the processing gases, e.g., CF₄, O₂, N₂, CHF₃, Ar, He, Xe and the like, may be independently controlled before their introduction into the chamber 102.

A gas exhaust pipe 131 is connected to a bottom portion of the chamber 102, and a gas exhaust unit 135 is connected to the gas exhaust pipe 131. The gas exhaust unit 135 includes a vacuum pump such as a turbo molecular pump or the like to control of the pressure inside the chamber 102 to a predetermined depressurized atmosphere, e.g., smaller than or equal to 0.67 Pa. Further, a gate valve 132 is provided at a sidewall of the chamber 102. By opening the gate valve 132, the wafer W can be loaded into and unloaded from the chamber 102. A wafer cassette, for example, is used for transferring the wafer W.

A first high frequency electric power supply 140 is connected to the upper electrode 121, and a first matching unit 141 is interposed at a feeder line thereof. Further, a low pass filter (LPF) 142 is connected to the upper electrode 121. The first high frequency electric power supply 140 can output an electric power having a frequency of 50 to 150 MHz. By applying an electric power having such high frequency to the upper electrode 121, a high-density plasma in a desirably dissociated state can be formed in the chamber 102, thereby enabling a plasma processing to be performed under a lower pressure condition than a conventional pressure condition. The frequency of the output electric power from the first high frequency electric power supply 140 preferably ranges from 50 MHz to 80 MHz. Typically, a frequency of around 60 MHz shown in FIG. 1 is used.

A second high frequency electric power supply 150 is connected to the susceptor 105 serving as a lower electrode, and a second matching unit 151 is interposed at a feeder line thereof. The second high frequency electric power supply 150 can output a electric power having a frequency ranging from several hundreds kHz to less than several tens MHz. By applying an electric power having such frequency to the susceptor 105, it is possible to facilitate a proper ion action on the wafer W without inflicting damages thereon. The frequency of the output electric power from the second high frequency electric power supply 150 is typically chosen to be 2 MHz, 3.2 MHz or 13.56 MHz as illustrated in FIG. 1. In this embodiment, the frequency thereof is chosen to be 2 MHz.

A2. Film Structure of an Object to be Processed

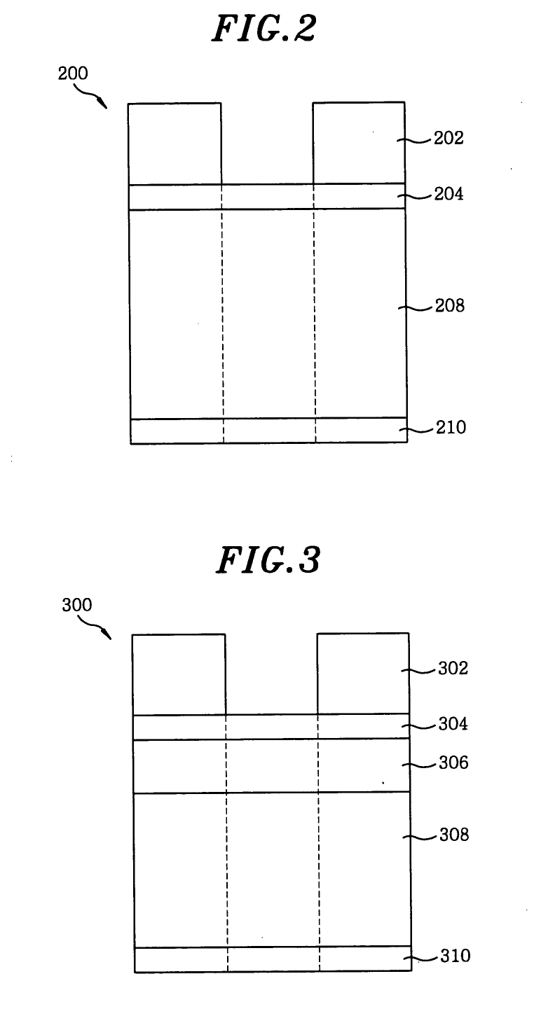

Hereinafter, there will be described with reference to FIGS. 2 and 3 two exemplary objects to be processed on which an etching process and an ashing process are performed by the plasma processing apparatus 101 illustrated in FIG. 1.

A first exemplary object to be processed 200 illustrated in FIG. 2 includes sequentially laminated layers of an etching stop film 210, a low dielectric constant film 208 (hereinafter, referred to as ‘low-k film’), a bottom anti-reflective coat (BARC) 204; and a photoresist film 202. Further, although it is not shown in FIG. 2, a metal layer, e.g., a Cu wiring layer or the like, various semiconductor layers and a silicon substrate may exist under the etching stop film 210.

The resist material forming the photoresist film 202 may be of a type sensitized to, e.g., a KrF light (a wavelength of 248 nm), and a film thickness thereof may be chosen to be 400 nm. Further, a circular hole having a diameter of 200 nm has been previously patterned in a photolithography process.

The bottom anti-reflective coat 204 serves to suppress a reflection light from the under layer when the photoresist film 202 is exposed to the KrF light. Accordingly, a finer patterning can be carried out. Further, the film thickness of the bottom anti-reflective coat 204 is chosen to be 60 nm.

A low dielectric constant material forming the low-k film 208 may include siloxane-based (Si—O—Si) hydrogen-silsesquioxane (HSQ), methyl-hydgrogen-silsesquioxane (MSQ) or the like. Further, an organic material can be employed other than the siloxane-based material. In this embodiment, Black Diamond (registered trademark) or Coral (registered trademark) as MSQ may be employed as the material forming the low-k film 208. Further, the film thickness of the low-k film 208 is chosen to be 1000 nm.

The etching stop film 210 is made of, e.g., a SiC material, and the film thickness thereof is chosen to be 80 μm. Due to the etching stop film 210, when the low-k film 208 is etched with the photoresist film 202 as a mask, a lower layer (e.g., a metal layer) of the etching stop film 210 is not affected by the etching process.

By performing the plasma etching process on the object to be processed 200 illustrated in FIG. 2 by using the plasma processing apparatus 101 illustrated in FIG. 1, the bottom anti-reflective coat 204 and the low-k film 208 are etched, thereby forming “via holes” having a diameter of 200 nm on the low-k film 208. Processing conditions involved herein will be described later.

A second exemplary object to be processed 200 shown in FIG. 3 includes sequentially laminated layers of an etching stop film 310, a low-k film 308, a silicon oxide film 306; a bottom anti-reflective coat 304; and a photoresist film 302. Further, although it is not shown in FIG. 3, a metal layer, e.g., a Cu wiring layer or the like, various semiconductor layers and a silicon substrate may exist under the etching stop film 310.

The resist material forming the photoresist film 302 may be of a type sensitized to, e.g., a ArF light (a wavelength of 193 nm), and the film thickness thereof is chosen to be 370 nm. Further, the so-called line•and•space•pattern having the line width and the inter-line width of 140 nm respectively has been previously patterned in the photolighography process.

The bottom anti-reflective coat 304 serves to suppress a reflection light from the under layer when the photoresist film 302 is exposed to the ArF light. Accordingly, a finer patterning can be carried out. Further, the film thickness of the bottom anti-reflective coat 304 is chosen to be 90 nm.

The silicon oxide film 306 has a film thickness of 100 nm.

The low dielectric constant material forming the low-k film 308 may include siloxane-based HSQ, MSQ or the like. In this embodiment, Black Diamond (registered trademark) or Coral (registered trademark) as said MSQ may be employed as the material forming the low-k film 308. Further, the film thickness of the low-k film 308 is chosen to be 1000 nm.

The etching stop film 310 is made of, e.g., a SiC material, and the film thickness thereof is chosen to be 50 μm. Due to the etching stop film 310, when the low-k film 308 is etched with the photoresist film 302 as a mask, the lower layer (e.g., a metal layer) of the etching stop film 310 is not affected by the etching process.

By performing the plasma etching process on the object to be processed 300 illustrated in FIG. 3 by using the plasma processing apparatus 101 illustrated in FIG. 1, the bottom anti-reflective coat 304, the silicon oxide film 306 and the low-k film 308 are etched, thereby forming a so-called line-and-space-pattern (trenches (grooves)) of which line width and the inter-line width of 140 nm respectively, on the low-k film 308.

A3. Processing Conditions in the Plasma Processing

Hereinafter, the plasma etching process and the plasma ashing process, which are performed on, e.g., the object to be processed 200 illustrated in FIG. 2, by using the plasma processing apparatus 101, will be described.

Above all, the bottom anti-reflective coat 204 is etched with the patterned photoresist film 202 as a mask (a first etching process). The processing conditions employed in the first etching process will now be described. The pressure in the chamber 102 is controlled to be 50 mTorr. A high frequency electric power of 1000 W and that of 100 W are applied to the upper electrode 121 and the susceptor 105, respectively. Further, CF₄ is used as the processing gas.

Next, etching of the low-k film 208 is performed with the patterned photoresist film 202 as a mask (a second etching process). The following processing conditions may be employed for the second etching process: a pressure in the chamber 102 of 50 mTorr; a high frequency electric power of 1200 W applied to the upper electrode 121; a high frequency electric power of 1700 W applied to the susceptor 105; and a processing gas having a mixture of CHF₃, CF₄, Ar, N₂ and O₂.

Thereafter, the so-called overetching process (a third etching process) may be carried out to prevent the low-k material from remaining on a bottom portion of the via holes formed on the low-k film 208 during the second etching process. The processing conditions in the third etching process may be described as follows. The pressure in the chamber 102 may be controlled to be 75 mTorr. A high frequency electric power of 1200 W may be applied to the upper electrode 121 and the susceptor 105. Further, a gaseous mixture of C₄F₈, Ar and N₂ may be used as a processing gas.

By performing the aforementioned first to third etching processes, the via holes are formed on the low-k film 208.

Thereafter, the plasma ashing process is performed on the object to be processed 200 in order to remove the photoresist film 202 in the same chamber 102.

However, as the first to third plasma etching processes are performed on the object to be processed 200, fluorine contained in the processing gas may be adhered to an inner wall of the chamber 102 and gradually deposited as a fluorine polymer. In such state, if the plasma ashing process is carried out to remove only the photoresist film 202, the fluorine polymer deposited on the inner wall of the chamber 102 may be redissociated, resulting in an etching of the low-k film 208.

Therefore, the plasma ashing process in accordance with this embodiment is respectively divided into a first ashing process for removing the fluorine polymer deposited on the inner wall of the chamber 102 and a second ashing process for removing the photoresist film 202. First of all, by performing the first ashing process, the fluorine polymer deposited on the inner wall of the chamber 102 is removed without affecting the object to be processed 200. Accordingly, in the following second ashing process, there is no redissociation of the fluorine polymer and, thus, the low-k film 208 will not be etched.

Further, in the plasma ashing process in accordance with this embodiment, since the processing conditions in the first and the second ashing processes can be properly controlled, deterioration (e.g., an increase of a dielectric constant) of the quality of the low-k film 208 can be prevented. Exemplary processing conditions that may be applied to the plasma ashing process in accordance with this embodiment will now be described.

The processing conditions applied to the first ashing process, for example, are: a pressure of 20 mTorr in the chamber 102; a gap of 40 mm between the upper electrode 121 and the susceptor 105; a high frequency electric power of 500 W applied to the upper electrode 121; a high frequency electric power of 0 W applied to the susceptor 105 (i.e., a high frequency electric power is not applied to the susceptor 105); a processing gas (a first processing gas) having a mixture of Ar (a first unreactive gas) and O₂ having a flow rate ratio of 450/50 sccm/sccm (a gas flow rate of Ar/a gas flow rate of O₂); and a first ashing processing time of 45 seconds.

Processing conditions applied to the second ashing process, for example, are described as follows: a pressure in the chamber 102 at 10 mTorr; a gap of 55 mm between the upper electrode 121 and the susceptor 105; a high frequency electric power of 500 W applied to the upper electrode 121; a high frequency electric power of 200 W applied to the susceptor 105; a processing gas (a second processing gas) having a mixture of N₂ (a second unreactive gas) and O₂ having a flow rate ratio of 60/60 sccm/sccm (a gas flow rate of N₂/a gas flow rate of O₂); a pressure of a cooling gas on a backside of a center portion of the object to be processed 200 at 10 Torr; a pressure of a cooling gas on a backside of an edge portion of the object to be processed 200 at 35 Torr; each temperature of the upper electrode, the lower electrode and a sidewall in the chamber 102 adjusted to 60° C., 50° C. and 20° C., respectively; and a second ashing processing time of 26 seconds.

In addition, during transition periods among the first through third etching processes and between the first and the second ashing processes, the first and the second high frequency electric power supplies 140 and 150 for supplying a high frequency electric power to the upper electrode 121 and the susceptor 105, respectively, are turned off. Meanwhile, the pressure in the chamber 102, which is set to be 10 mTorr, during the second ashing process is too low to ignite a plasma in the chamber 102 in a stable manner. Therefore, a plasma ignition process is performed for three seconds between the first and the second ashing processes to thereby temporarily increase the pressure in the chamber 102 up to, e.g., 30 mTorr. By performing such plasma ignition process, it is possible to ignite the plasma securely and then lower the pressure in the chamber 102 for the following second ashing process.

As described above, a main reason for deteriorating the film quality of the low-k film 208 is that O contained in a processing gas becomes a radical, and the O radical changes a composition of a low-k material forming the low-k film 208. To address such drawback, the plasma ashing method in accordance with this embodiment prevents a production of the O radical mainly by optimizing two processing conditions. First, an inner pressure of the chamber 102 is lowered. Second, a gaseous mixture of O₂ gas and an unreactive gas is employed as a processing gas. Moreover, in order to prevent the O radical from being produced, it is effective to change a type of an unreactive gas to be combined with O₂ gas in the first and the second ashing processes, as described above. Further, by optimizing other parameters of the processing conditions, the O radical production can be further prevented. As a result, the film quality of the low-k film 208 can be maintained satisfactorily.

A3. Experiment of the Plasma Ashing Process

Hereinafter, there will be described optimal (or an optimal scope of) ashing processing conditions for maintaining the satisfactory film quality of the low-k films 208 and 308 based on a result of an experiment in which the plasma ashing process is performed on the objects to be processed 200 and 300 illustrated in FIGS. 2 and 3 by using the plasma processing apparatus 101 in accordance with this embodiment while varying various parameters.

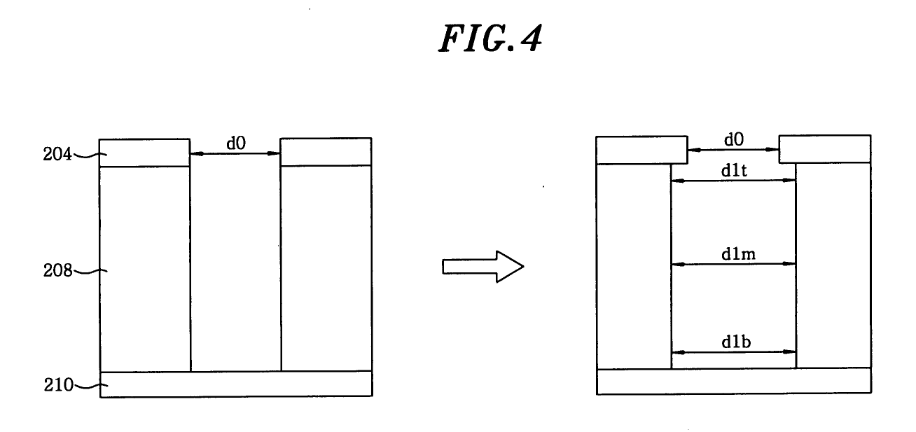

In this experiment, a degree of damage to the low-k film due to the plasma ashing process is judged based on a degree of erosion of the low-k film in soaking an object to be processed as a sample in a hydrofluoric acid. Such judging method uses properties that the low-k film (having a satisfactory film quality) does not dissolve in a hydrofluoric acid whereas the low-k film of which composition has changed is soluble in the hydrofluoric acid. The judging method will be described in detail with reference to FIG. 4.

An object to be processed obtained by performing the plasma etching process and the plasma ashing process on the object to be processed 200 of FIG. 2 is shown in a left side of an arrow in FIG. 4. A hole is formed on the low-k film 208 by the plasma etching process, and the photoresist film 202 is removed by the plasma ashing process. If the object to be processed 200 soaks in the hydrofluoric acid, in case the plasma ashing process inflicts damages on the low-k film 208, an exposed sidewall of the low-k film 208 is dissolved as illustrated in a right side of the arrow in FIG. 4. A dissolved amount Δd corresponds to an extent of the low-k film 208 of which composition has changed by the oxygen radical. Further, as the dissolved amount Δd increases, the plasma ashing process inflicts more damages on the low-k film 208. Furthermore, as illustrated in FIG. 4, the dissolved amount Δd is indicated by a change of an opening degree, i.e., a critical dimensions (CD) shift, of the hole (or a trench). In practice, the CD shift of the hole (or the trench) may be different in accordance with a depth direction. In this experiment, an upper hole diameter d1t, an intermediate hole diameter d1m and a bottom hole diameter d1b are measured, and a degree of damage to the low-k film is judged by using a value in a position having a largest CD shift. For instance, in case the diameter of the upper hole d1t is the largest value, the dissolved amount Δd is chosen to be a difference between a hole diameter d0 of the low-k film 208 before being soaked in the hydrofluoric acid and the upper hole diameter d1t of the low-k film 208 after being soaked in the hydrofluoric acid.

As described above, the plasma ashing processing method in accordance with this embodiment includes the first ashing process for removing the fluorine polymer deposited on the inner wall of the chamber 102 and the second ashing process for removing the photoresist film 202. Therefore, experiments are performed for each of the first and the second ashing processes.

A4. Relationships Between the CD Shift and Various Processing Conditions in the First Ashing Process

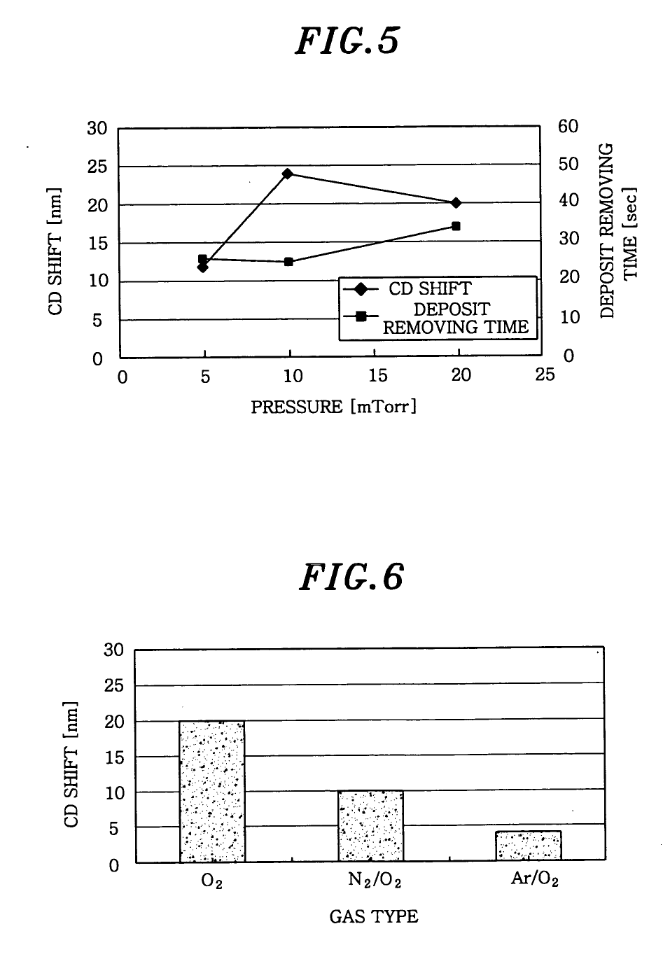

First, optimal processing conditions in the first ashing process will be examined based on experiment results illustrated in FIGS. 5 to 15.

Above all, the first ashing process is performed by using the object to be processed 200 (the low-k film 208 being Black Diamond (registered trademark)) having a via hole shown in FIG. 2. In this experiment, a gap between the upper electrode 121 and the susceptor 105 was controlled to be 40 mm. Further, a high frequency electric power of 500 W was applied to the upper electrode 121, and that of 0 W was applied to the susceptor 105 (i.e. a high frequency electric power is not applied to the susceptor 105). Further, an O₂ gas was used as a processing gas and a flow rate thereof was chosen to be 500 sccm. The CD shift was measured by varying a pressure in the chamber 102 under the above-described conditions. A result thereof is depicted in FIG. 5. In case the pressure in the chamber 102 is smaller than (or equal to) 20 mTorr, more preferably, smaller than (or equal to) 10 mTorr, the CD shift is slightly suppressed. Even if the pressure in the chamber 102 is smaller than or equal to 20 mTorr, time required for removing the fluorine polymer deposited on the inner wall of the chamber 102 is so short that an original purpose of the first ashing process can still be achieved.

Next, the first ashing process is performed by using the same sample under different processing conditions. In this experiment, a gap between the upper electrode 121 and the susceptor 105 was controlled to be 40 to 55 mm. Further, a high frequency electric power of 500 W was applied to the upper electrode 121, and that of 0 W was applied to the susceptor 105 (i.e. a high frequency electric power is not applied to the susceptor 105). Furthermore, the pressure in the chamber 102 was controlled to be 20 mTorr. Under such conditions, the CD shift was measured by changing processing gas species. Processing gases used in the experiment are O₂ gas (a single gas), a gaseous mixture of N₂ and O₂, and a gaseous mixture of Ar and O₂. A total flow rate of each processing gas ranges from 120 sccm to 500 sccm, and a flow rate ratio of the gaseous mixture was set to be 1:1. A result thereof is illustrated in FIG. 6. A desirable result was obtained by using a gaseous mixture of an unreactive gas, e.g., a N₂ gas, an Ar gas or the like, and an O₂ gas rather than using the O₂ gas alone. Especially, it is most efficient to employ the gaseous mixture of Ar and O₂ as a processing gas in order to prevent a deterioration of a film quality of the low-k film.

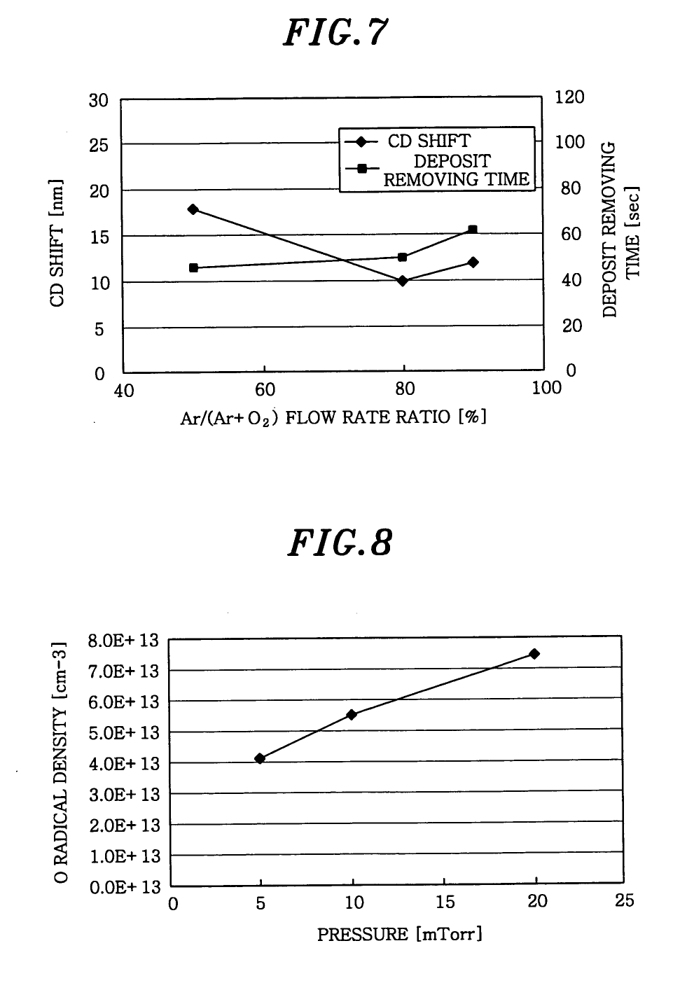

Thereafter, a desirable mixing ratio (a flow rate ratio) of the gaseous mixture of Ar and O₂, which provides a preferable result in the above-described experiment, was investigated. A result thereof is described in FIG. 7. Processing conditions except the mixing ratio of the processing gas are equal to those in the experiment of which result is shown in FIG. 6. In this experiment, however, Coral (registered trademark) was used as the low-k film 208. As illustrated in FIG. 7, as a ratio of Ar gas increases from 50% to 80% (i.e., as a ratio of O₂ gas decreases), the CD shift decreases. A most preferable condition of the flow rate ratio between an Ar gas and an O₂ gas is determined to be about 8:2. Time required for removing the fluorine polymer deposited on the inner wall of the chamber 102 is maintained as a short period of time when the flow rate ratio ranges from 50% to 80%. From this point, the flow rate ratio of about 8:2 between the Ar gas and the O₂ gas is regarded as the most desirable condition.

A5. Plasma Observation Result in the First Ashing Process

Next, a relationship between the density of O radical which is considered to be a main reason for deteriorating the film quality of the low-k film, and the pressure in the chamber 102 was investigated by an experiment. In this experiment, a gap between the upper electrode 121 and the susceptor 105 was controlled to be 40 mm. Further, a high frequency electric power of 500 W was applied to the upper electrode 121, and that of 0 W was applied to the susceptor 105 (i.e. a high frequency electric power is not applied to the susceptor 105). Furthermore, a gaseous mixture of Ar and O₂ was used as a processing gas, wherein a gas flow rate ratio between Ar and O₂ (a gas flow rate of Ar gas/a gas flow rate of O₂) was set to be 400/100 sccm/sccm. As depicted in FIG. 8, in case the pressure in the chamber 102 was smaller than (or equal to) 20 mTorr, the O radical density becomes sufficiently low. Further, it is found that as the pressure decreases, the O radical density gets lower. Therefore, in order to prevent a deterioration of the low-k film, it is preferable to control an inner pressure of the chamber 102 low, specifically, smaller than (or equal to) 20 mTorr.

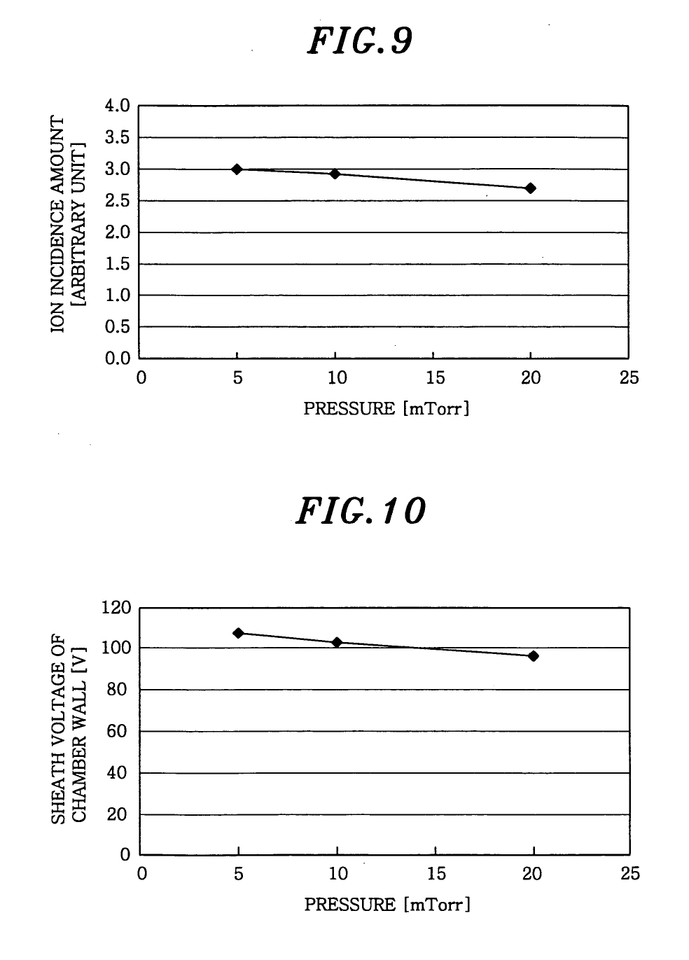

FIG. 9 presents a relationship between an ion incidence amount on the object to be processed and the pressure in the chamber 102. As clearly shown in FIG. 9, when the pressure in the chamber 102 is lowered, the increase in the amount of the ion incidence is negligible. Therefore, the decrease in the pressure in the chamber 102 is considered to be irrelevant to the deterioration of the low-k film by the ion incidence.

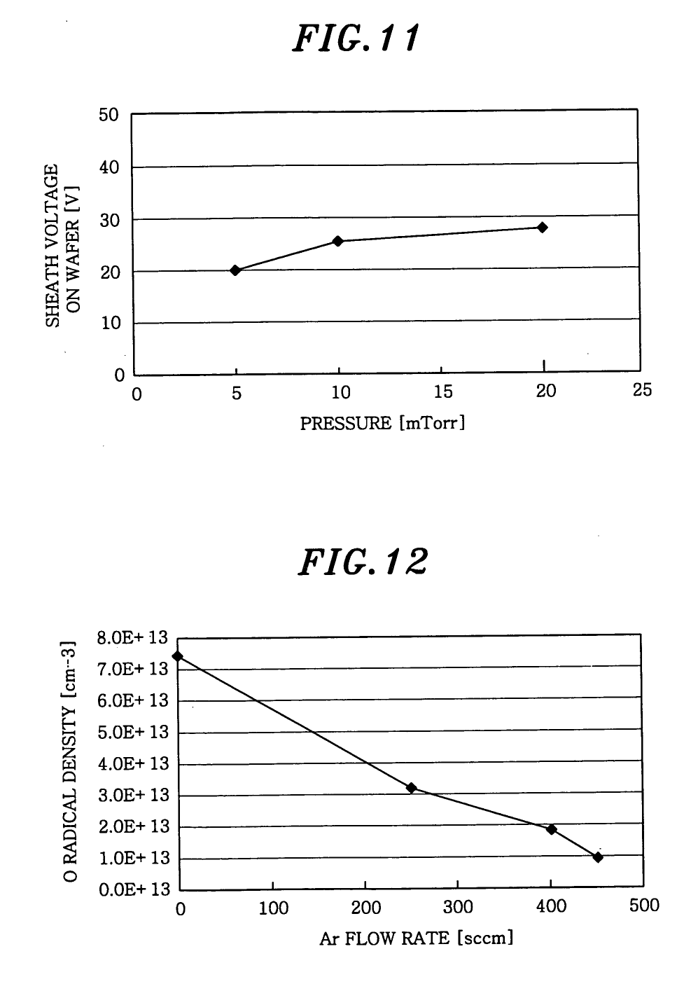

Next, an experiment was carried out to obtain a relationship between a sheath voltage of a wall of the chamber 102 and a pressure in the chamber 102 and that between a sheath voltage on a wafer and a pressure in the chamber 102. If the pressure in the chamber 102 is lowered, the sheath voltage of the wall of the chamber 102 increases as illustrated in FIG. 10, whereas the sheath voltage on the wafer decreases as shown in FIG. 11. In accordance with such experiment result, if the pressure in the chamber 102 is lowered, an ashing on the wall of the chamber 102 exceeds that on the wafer, thereby not inflicting damages on the low-k film.

Although the relationship between the O radical density and the pressure in the chamber 102 has already been described with reference to FIG. 8, a following experiment has been performed to obtain a relationship between the O radical density and a flow rate ratio between Ar and O₂. In this experiment, the pressure in the chamber was controlled to be 20 mTorr. Further, each flow rate of Ar gas and O₂ gas was varied while maintaining a total flow rate of 500 sccm in the gaseous mixture of Ar and O₂ as a processing gas. Other processing conditions are equal to those in the experiment of which result is shown in FIG. 8. As depicted in FIG. 12, as the flow rate of Ar gas increases, the O radical density becomes low. Thus, in order to prevent a deterioration of the low-k film, it is preferable to increase a ratio of Ar gas to be contained in the processing gas and, specifically, control a flow rate ratio between Ar gas and O₂ gas to be 400:100.

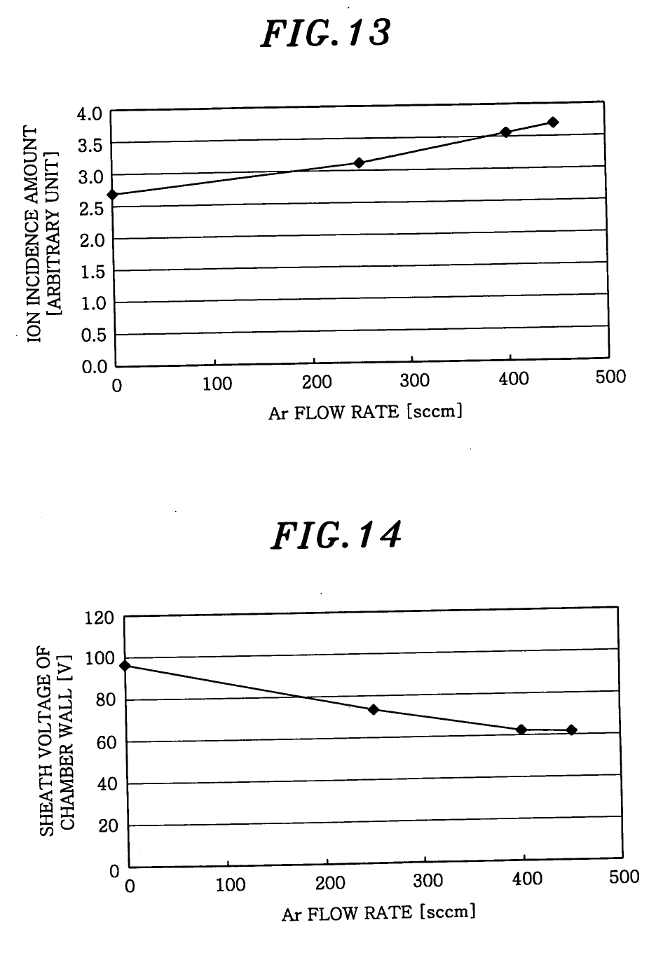

FIG. 13 represents a relationship between an ion incidence amount on the object to be processed and a flow rate of Ar gas. As clearly shown in FIG. 13, when the flow rate of Ar gas increases, the increase in the amount of the ion incidence is negligible. Thus, the increase in the flow rate of Ar gas is considered to be irrelevant to the deterioration of the low-k film by the ion incidence.

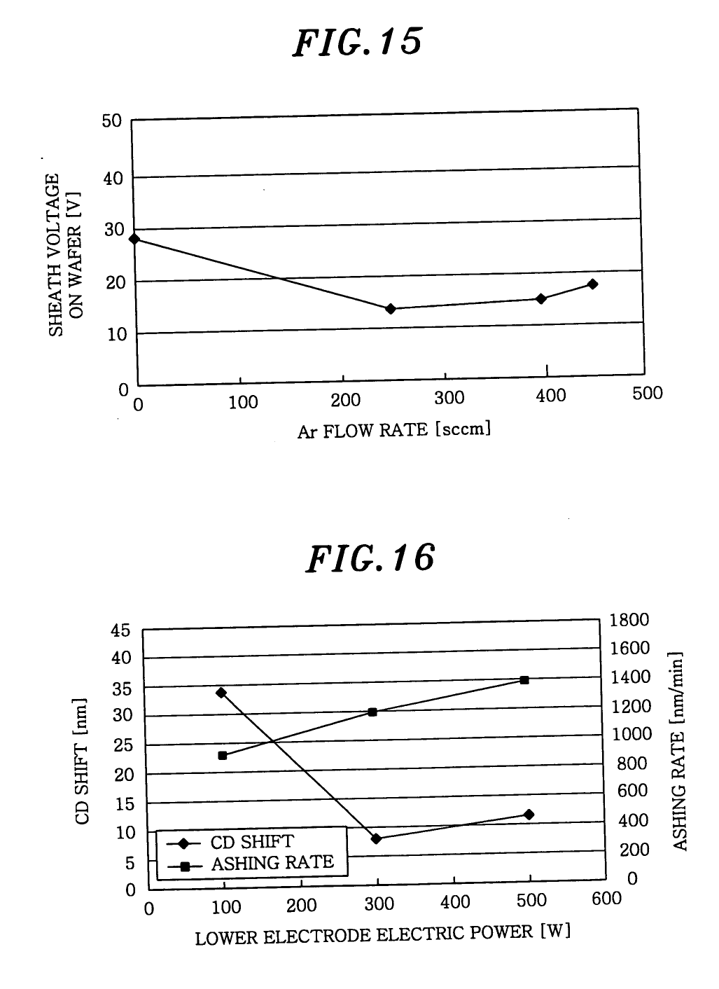

An experiment has been performed to obtain a relationship between the sheath voltage of the wall of the chamber 102 and the flow rate of Ar gas (the Ar/O₂ flow rate ratio) and that between the sheath voltage on the wafer and the flow rate of Ar gas (the Ar/O₂ flow rate ratio) . If the flow rate of Ar gas increases from 0 sccm (i.e., only O₂ gas is used as the processing gas) to 400 sccm, the sheath voltage of the wall of the chamber 102 decreases as illustrated in FIG. 14, and the sheath voltage on the wafer also decreases as shown in FIG. 15. However, the former decreasing rate is about 30%, whereas the latter decreasing rate is about 50%. In other words, the sheath voltage on the wafer drops more than that of the chamber wall when Ar gas flow rate increases. In accordance with such experiment result, if the flow rate (ratio) of Ar gas increases, an ashing on the wall of the chamber 102 exceeds that on the wafer, thereby not inflicting damages on the low-k. So far, the results of the experiments for obtaining the optimal processing conditions in the first ashing process and the optimal processing conditions obtained therefrom have been described.

A6. Relationships Between the CD Shift and Various Processing Conditions in the Second Ashing Process

Next, optimal processing conditions in the second ashing process will be examined based on experiment results shown in FIGS. 16 to 29. Further, hereinafter, as long as a specific description is not provided, the object to be processed 200 having via holes or the object to be processed 300 having trenches is set for an experiment for searching for the optimal processing conditions of the second ashing process in the plasma processing apparatus 101 that has been cleaned. Accordingly, the experiment result can be free from effects of the first ashing process.

First, the second ashing process was performed by using the object to be processed 200 (the low-k film 208 being Black Diamond (registered trademark)) having the via hole illustrated in FIG. 2. In this experiment, a gap between the upper electrode 121 and the susceptor 105 was controlled to be 40 mm, and the pressure in the chamber was controlled to be 20 mTorr. Further, a high frequency electric power applied to the upper electrode 121 was controlled to be 1000 W. Moreover, O₂ gas was used as a processing gas, and a flow rate thereof was chosen to be 200 sccm. Under such conditions, the CD shift was measured by changing a high frequency electric power (a lower electrode electric power) applied to the susceptor 105. A result thereof is shown in FIG. 16. In accordance with such result, when the lower electrode electric power ranges from 100 W to 500 W, the CD shift is slightly suppressed. A range of the lower electrode electric power is especially preferable between 300 W and 500 W. In addition, the wafer used in this experiment has a diameter of 200 mm, and a diameter of a focus ring surrounding the wafer is chosen to be 260 mm. Therefore, the lower electrode electric power of 100˜300˜500 W corresponds to an electric power density of about 0.19˜0.57˜0.94 W/cm².

As described above, an ashing rate of the photoresist film 202, which was obtained by controlling the lower electrode electric power to range from 100 to 500 W, was ascertained by the experiment. In this experiment, however, a sample in which a photoresist material is coated on an entire surface of the wafer (hereinafter, referred to as ‘PR blanket sample’) was used. As described in FIG. 16, a satisfactory ashing rate is also obtained when the lower electrode electric power ranges from 100 W to 500 W. Especially, the ashing rate increases when the lower electrode electric power ranges from 300 W to 500 W, making it more preferable. Accordingly, by appropriately controlling the lower electrode electric power, the original purpose of the second ashing process, i.e., an efficient removal of the photoresist film and a film quality maintenance of the low-k film, can be achieved.

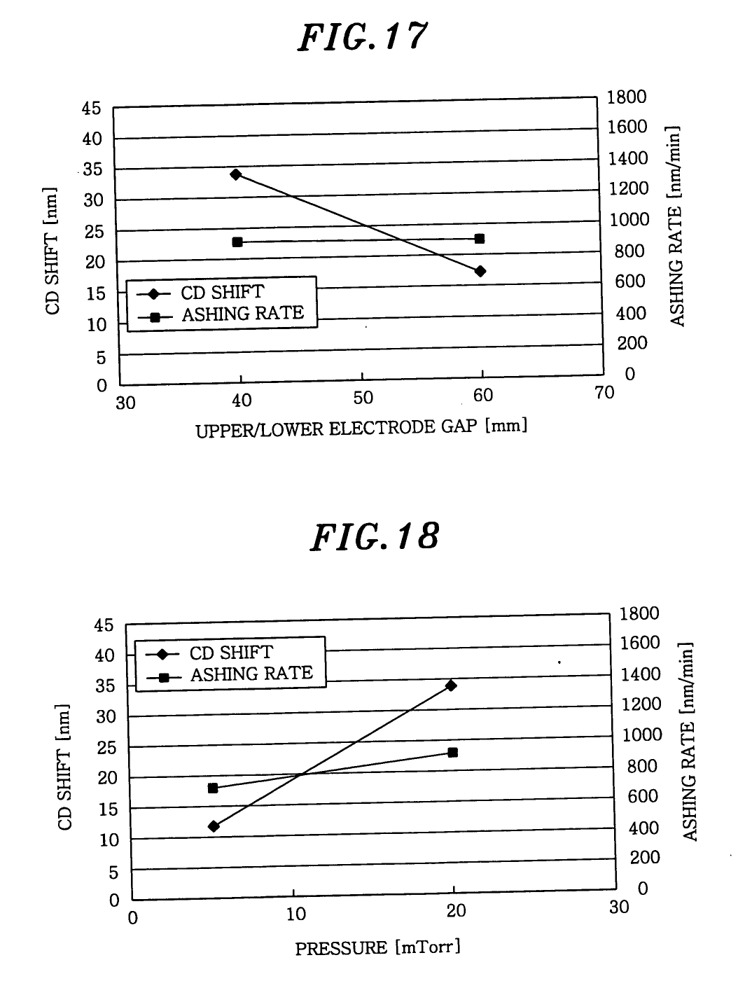

Next, the second ashing process was performed by using the same sample under different processing conditions. In this experiment, a high frequency electric power of 1000 W and that of 150 W were applied to the upper electrode 121 and the susceptor 105, respectively. Further, the pressure in the chamber was controlled to be 20 mTorr. Moreover, an O₂ gas was used as a processing gas, and a flow rate thereof was chosen to be 200 sccm. Under such conditions, the CD shift was measured by changing a gap between the upper electrode 121 and the susceptor (a lower electrode) 105. A result thereof is illustrated in FIG. 17. In accordance with such result, as the gap between the upper electrode 121 and the susceptor (the lower electrode) 105 increases within the range of 40 to 60 mm, the CD shift is slightly suppressed.

As described above, the ashing rate of the photoresist film 202, which was obtained by controlling the gap between the upper electrode 121 and the susceptor (the lower electrode) 105 to range from 40 mm to 60 mm, was ascertained by the experiment using the PR blanket sample. As depicted in FIG. 17, the satisfactory ashing rate can also be obtained when the gap between the upper electrode 121 and the susceptor (the lower electrode) 105 ranges from 40 mm to 60 mm.

Thereafter, the second ashing process was carried out by using the same sample under different processing conditions. In this experiment, a gap between the upper electrode 121 and the susceptor 105 was controlled to be 40 mm, and a high frequency electric power of 1000 W and that of 150 W were applied to the upper electrode 121 and the susceptor 105, respectively. Besides, O₂ gas was used as a processing gas, and a flow rate thereof was chosen to be 200 sccm. Under such conditions, the CD shift was measured by changing a pressure in the chamber 102. A result thereof is shown in FIG. 18. As the pressure in the chamber 102 is lowered within the range of 5 to 20 mTorr, the CD shift is slightly suppressed.

Furthermore, as described above, the ashing rate of the photoresist film 202, which was obtained by controlling the pressure in the chamber 102 to be smaller than or equal to 20 mTorr, was examined by the experiment using the PR blanket sample. As illustrated in FIG. 18, although the satisfactory ashing rate is obtained even in case the pressure in the chamber 102 is smaller than or equal to 20 mTorr, the ashing rate becomes smaller as the pressure is lowered. Therefore, by appropriately controlling the pressure in the chamber 102, both the efficient removal of the photoresist film and the film quality maintenance of the low-k film can be achieved.

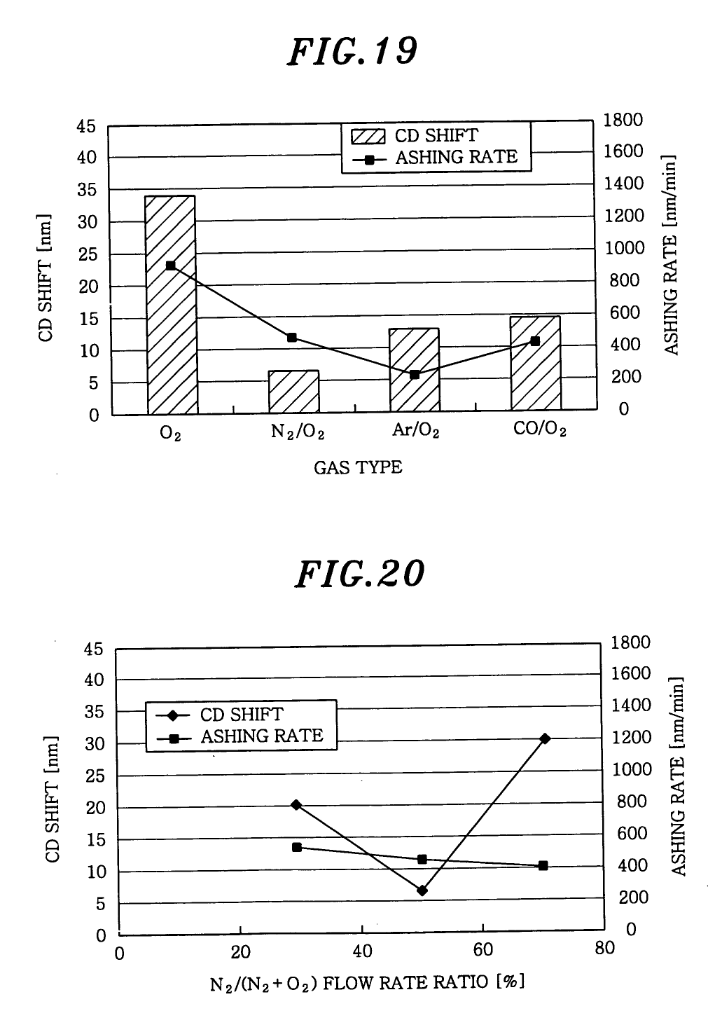

Then, the ashing process was performed by using the same sample under different processing conditions. In this case, a gap between the upper electrode 121 and the susceptor 105 was controlled to range from 40 mm to 55 mm, and a high frequency electric power of between 500 W and 1000 W and that between 100 W and 150 W were applied to the upper electrode 121 and the susceptor 105, respectively. Besides, the pressure inside the chamber 102 was controlled to be 10 to 20 mTorr. Under such conditions, the CD shift was measured by changing a processing gas. The processing gas used in this experiment was O₂ gas (a single gas), a gaseous mixture of N₂ and O₂, a gaseous mixture of Ar and O₂, and a gaseous mixture of CO and O₂. Further, a total flow rate of processing gas ranges from 10 sccm to 100 sccm. In case of the gaseous mixture, a flow rate ratio is chosen to be 1:1. A result of the experiment is shown in FIG. 19. A desirable result was obtained by using a gaseous mixture of an unreactive gas, e.g., N₂ gas, Ar gas or the like, or CO gas and O₂ gas instead of using an O₂ single gas. Especially, it is most efficient to employ the gaseous mixture of N₂ and O₂ as a processing gas in order to maintain the film quality of the low-k film.

Furthermore, as described above, an ashing rate of the photoresist film 202, which was obtained by changing processing gas species, was examined by the experiment using the PR blanket sample. As shown in FIG. 19, although O₂ gas (a single gas) shows the highest ashing rate, the gaseous mixture of N₂ and O₂, which has a high suppressive effect on the CD shift, shows a relatively high ashing rate as well. By employing the gaseous mixture of N₂ and O₂, it is possible to achieve both the efficient removal of the photoresist film and the film quality maintenance of the low-k film.

Next, a desirable mixing ratio (a flow rate ratio) of the gaseous mixture of N₂ and O₂, which provides a preferable result in the above-described experiment, was examined. A result thereof is described in FIG. 20. In this experiment, a gap between the upper electrode 121 and the susceptor 105 was controlled to be 55 mm, and a high frequency electric power of 500 W and that of 100 W were applied to the upper electrode 121 and the susceptor 105, respectively. Further, the pressure in the chamber 102 was controlled to be 10 mTorr, and a total flow rate of the gaseous mixture of N₂ and O₂ was set to be 120 sccm. Moreover, in this experiment, Coral (registered trademark) was used as the low-k film 208. As clearly can be seen from FIG. 20, when an amount of N₂ gas ranges from 30% to 70%, the CD shift is slightly suppressed. To be more specific, when an amount of N₂ gas is nearly equal to that of O₂ gas, the CD shift becomes smallest.

In addition, as described above, an ashing rate of the photoresist film 202, which was obtained by changing a mixing ratio of the gaseous mixture of N₂ and O₂, was ascertained by the experiment using the PR blanket sample. As shown in FIG. 20, a satisfactory ashing rate is obtained when an amount of N₂ gas ranges from 30% to 70%. Therefore, by controlling the amount of N₂ gas within the range of 30 to 70%, it is possible to achieve both the efficient removal of the photoresist film and the film quality maintenance of the low-k film.

A7. Relationships Between the CD Shift and Various Processing Conditions of the Second Ashing Process in Successively Performing the First and the Second Ashing Processes

The above description provides the results obtained by setting the object to be processed 200 having the via holes in the plasma processing apparatus 101 that has been cleaned and then performing the second ashing process thereon. Meanwhile, experiment results obtained by successively performing the first and the second ashing processes are described in FIGS. 21 to 23.

Above all, an experiment of which result is shown in FIG. 21 will be described. In this experiment, the first ashing process was performed by employing the object to be processed 300 (the low-k film 209 being Black Diamond (registered trademark)) which has a trench shown in FIG. 3. In the first ashing process, the pressure in the chamber was controlled to be 20 mTorr, and a gap between the upper electrode 121 and the susceptor 105 was controlled to be 40 mm. Further, a high frequency electric power of 500 W was applied to the upper electrode 121, and that of 0 W was applied to the susceptor 105 (i.e., a high frequency electric power was not applied to the susceptor 105). Moreover, a gaseous mixture of Ar and O₂ having flow rates of 400/100 sccm/sccm was used as a processing gas. Next, the second ashing process was performed. The pressure in the chamber was controlled to be 10 mTorr, and a gap between the upper electrode 121 and the susceptor 105 was controlled to be 55 mm. Further, a high frequency electric power of 500 W and that of 100 W were applied to the upper electrode 121 and the susceptor 105, respectively. In addition, a gaseous mixture of N₂ and O₂ was used as a processing gas, and a total flow rate thereof was set to be 120 sccm. In this experiment, the CD shift was measured by varying a flow rate ratio of N₂ gas within the range of 50 to 90% under the aforementioned conditions. As clearly shown in FIG. 21, the CD shift is slightly suppressed when the flow rate ratio of N₂ gas ranges from 50% to 90%. As the flow rate ratio of N₂ gas increases, the CD shift having a peak value at 70% decreases.

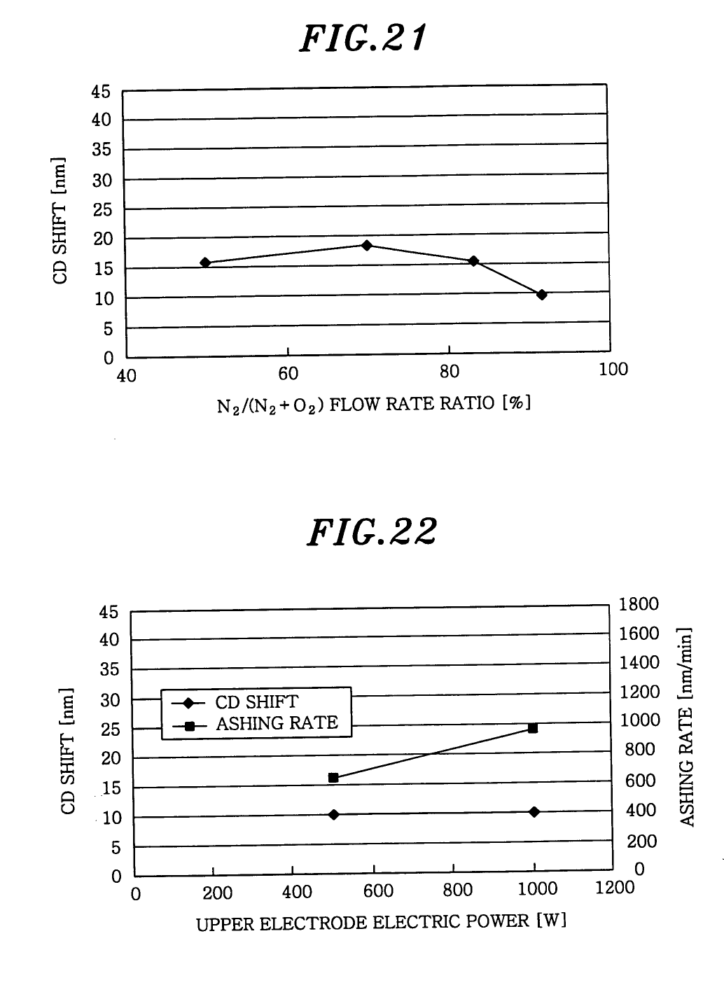

Hereinafter, an experiment of which result is depicted in FIG. 22 will be described. In this experiment, the first ashing process was performed by using the object to be processed (the low-k film 208 being Coral (registered trademark)) having the via hole shown in FIG. 2. In the first ashing process, the pressure in the chamber was controlled to be 20 mTorr, and a gap between the upper electrode 121 and the susceptor 105 was controlled to be 40 mm. Further, a high frequency electric power of 500 W was applied to the upper electrode 121, and that of 0 W was applied to the susceptor 105 (i.e., a high frequency electric power is not applied to the susceptor 105). Moreover, a gaseous mixture of Ar and O₂ having flow rates of 450/50 sccm/sccm was used as a processing gas. Thereafter, the second ashing process was carried out. In this case, the pressure in the chamber was controlled to be 10 mTorr, and a gap between the upper electrode 121 and the susceptor 105 was controlled to be 55 mm. Further, a high frequency electric power of 500 W was applied to the susceptor 105. Moreover, a gaseous mixture of N₂ and O₂ each having a flow rate of 60 sccm was used as a processing gas. In this experiment, the CD shift was measured by varying the high frequency electric power (an upper electrode electric power) applied to the upper electrode 121 within the range of 500 to 1000 W under the aforementioned conditions. As clearly shown in FIG. 22, the CD shift is nearly constantly and slightly suppressed when an upper electrode electric power ranges from 500 W to 1000 W.

Further, as described above, an ashing rate of the photoresist film 202, which was obtained by varying the upper electrode electric power within the rage of 500 to 1000 W, was examined. As shown in FIG. 22, as the upper electrode electric power increases, a high ashing rate can be obtained. Therefore, if the upper electrode electric power is controlled to be, e.g., 1000 W, it is possible to achieve both the efficient removal of the photoresist film and the film quality maintenance of the low-k film.

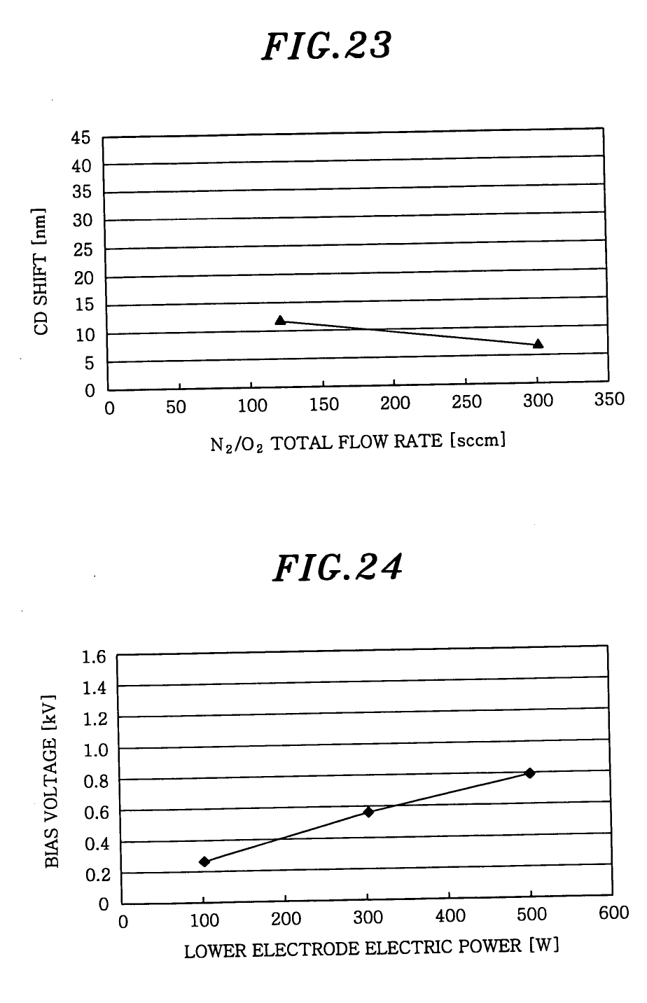

Next, an experiment of which result is illustrated in FIG. 23 will be described. In this experiment, the first ashing process was performed by using the object to be processed (the low-k film 208 being Coral (registered trademark)) having the via hole shown in FIG. 2. In the first ashing process, the pressure in the chamber 102 was controlled to be 20 mTorr, and a gap between the upper electrode 121 and the susceptor 105 was set to be 40 mm. Further, a high frequency electric power of 500 W was applied to the upper electrode 121, and that of 0 W was applied to the susceptor 105 (i.e., a high frequency electric power is not applied to the susceptor 105). Moreover, a gaseous mixture of Ar and O₂ having flow rates of 450/50 sccm/sccm was used as a processing gas. Thereafter, the second ashing process was carried out. In this case, the pressure in the chamber was controlled to be 10 mTorr, and a gap between the upper electrode 121 and the susceptor 105 was controlled to be 55 mm. Further, a high frequency electric power of 500 W and that of 200 W were applied to the upper electrode 121 and the susceptor 105, respectively. Moreover, a gaseous mixture of N₂ and O₂ was used as a processing gas, and a flow rate ratio thereof was chosen to be 1:1. In this experiment, the CD shift was measured by varying a total flow rate of the gaseous mixture of N₂ and O₂ within the range of 120 to 300 sccm while maintaining the flow rate ratio at 1:1 under the aforementioned conditions. As clearly can be seen from FIG. 23, an increase in the total flow rate of the gaseous mixture of N₂ and O₂ causes decreases in the CD shift, and a most desirable result is obtained when the total flow rate thereof is about 300 sccm. As described above, by performing the experiment for obtaining the relationships between the various processing conditions of the second ashing process and the CD shift (and the ashing rate), it is possible to search for processing conditions for maintaining a satisfactory film quality of the low-k film.

A8. Plasma Observation Result in the Second Ashing Process

Next, a plasma measurement experiment in the second ashing process was performed and, further, optimal processing conditions were searched.

First of all, in order to get a second knowledge of a relationship between a high frequency electric power (a lower electrode electric power) applied to the susceptor 105 and an ion incidence amount on an object to be processed, the lower electrode electric power and a bias voltage applied to the object to be processed were measured. A measurement result is shown in FIG. 24. As clearly shown in FIG. 24, as the lower electrode electric power increases from 100 W to 500 W, the bias voltage applied to the object to be processed also increases. The increase in the bias voltage causes increase in the ion incidence amount on the object to be processed, thereby facilitating an anisotropic etching (ashing) by ions. Further, in this experiment, the high frequency electric power (an upper electrode electric power) applied to the upper electrode 121 was set to be 1500 W.

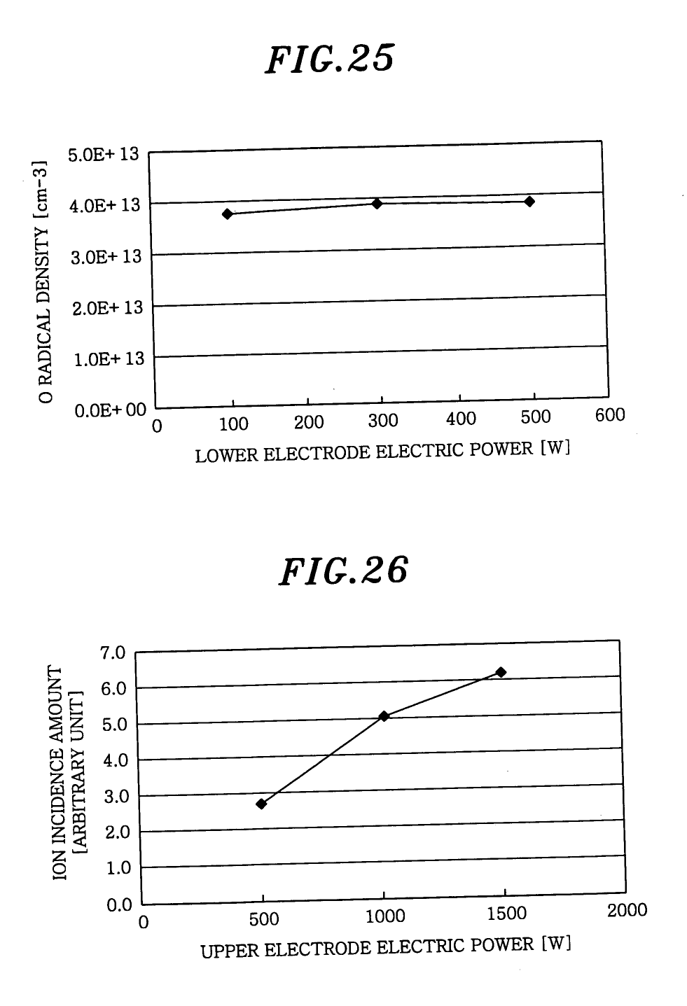

Further, a relationship between the O radical density regarded as a main reason of the CD shift and the lower electrode electric power was ascertained by the experiment. A result thereof is depicted in FIG. 25. As clearly shown in FIG. 25, even if the lower electrode electric power changes between 100 W to 500 W, the O radical density in the chamber 102 remains nearly constant. Such experiment result provides the following points. If the lower electrode electric power increases from 100 W to 500 W, an ion amount increases and, further, the photoresist film can be removed in a short period of time by the ashing. Meanwhile, since the amount of O radical does not increase despite the increase in the lower electrode electric power, a film quality of the low-k film can be maintained in a satisfactory state. Further, since a moving direction of ions has a high anisotropy unlike the O radical, an exposed sidewall of the low-k film is not etched even if the ion amount increases.

Thereafter, a relationship between a high frequency electric power (an upper electrode electric power) applied to the upper electrode 121 and an ion incidence amount on an object to be processed was examined. A result thereof is shown in FIG. 26. As clearly shown in FIG. 26, if the upper electrode electric power increases from 500 W to 1500 W, the ion incidence amount also increases. As a result, an anisotropic etching (ashing) by ions is facilitated. Furthermore, in this experiment, the lower electrode electric power was set to be 100 W.

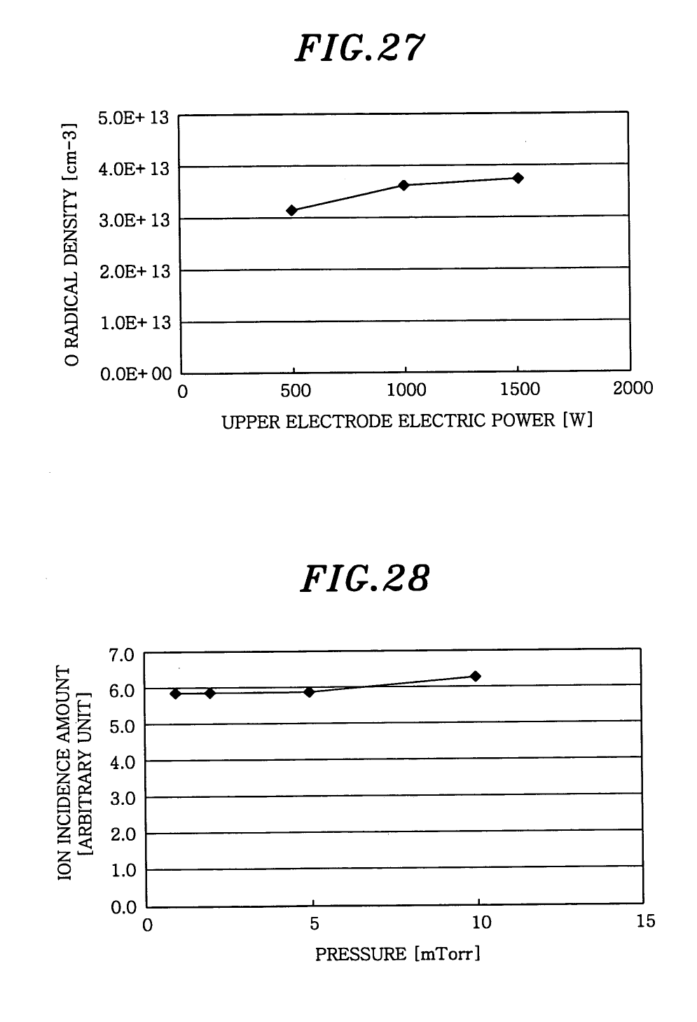

Next, a relationship between the density of O radical which is considered to be a main reason of the CD shift and a high frequency electric power (an upper electrode electric power) applied to the upper electrode 121 was examined by the experiment. A result thereof is depicted in FIG. 27. As clearly shown in FIG. 27, in case the upper electrode electric power increases from 500 W to 1500 W, the O radical density slightly increases. The following conclusions can be obtained from results shown in FIGS. 26 and 27. In other words, by controlling the upper electrode electric power within the range of 500 to 1500 W, preferably, to be 1500 W, it is possible to efficiently remove the photoresist film and suppress damage to the low-k film. Further, in this embodiment, a diameter of the upper electrode 121 is chosen to be, e.g., 280 mm. Therefore, the upper electrode electric power of 500 to 1500 W has an electric power density of about 0.81 to 2.44 W/cm².

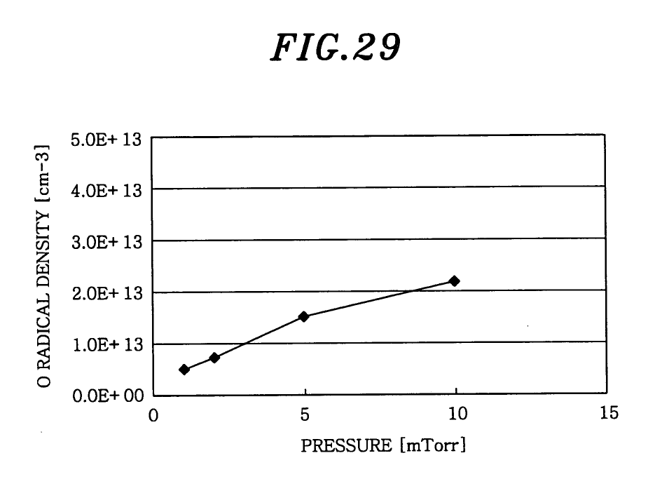

FIG. 28 offers a relationship between an ion incidence amount on an object to be processed and a pressure in the chamber 102. As clearly shown in FIG. 28, even if the pressure in the chamber 102 is lowered, the ion incidence amount remains nearly constant. In the meantime, as illustrated in FIG. 29, if the pressure in the chamber 102 is lowered, the O radical density decreases. Specifically, in case the pressure in the chamber 102 is lowered, a density of the O radical causing an isotropic etching reaction decreases, thereby not inflicting damages on the low-k film. Further, even if the pressure in the chamber 102 is lowered, an ion amount required for an anisotropic etching (ashing) reaction is not changed and, therefore, the photoresist film can be efficiently removed in a short period of time.

Moreover, a relationship between a mixing ratio (a flow rate ratio) of a gaseous mixture of N₂ and O₂ as a processing gas and an ion incidence amount on an object to be processed and that between the mixing ratio (the flow rate ratio) thereof and the O radical density were ascertained by the experiment. In accordance with this experiment, even if the flow rate ratio of the gas changes, the ion incidence amount remains nearly constant, whereas if a flow rate of N₂ gas increases, the O radical density decreases. Therefore, by increasing the flow rate of N₂ gas, it is possible to efficiently remove the photoresist film while suppressing damages to the low-k film. Furthermore, a relationship between a total flow rate of a gaseous mixture of N₂ and O₂ as a processing gas and an ion incidence amount on an object to be processed and that between the total flow rate thereof and the O radical density were examined by the experiment. In accordance with this experiment, even if the total flow rate of the gaseous mixture changes, the ion incidence amount remains nearly constant, whereas if the total flow rate of the gaseous mixture increases, the O radical density decreases. Therefore, by increasing the total flow rate of the gaseous mixture of N₂ and O₂, it is possible to efficiently remove the photoresist film and suppress damage to the low-k film.

As clearly shown in the above-described experiment results, by lowering the pressure in the chamber 102 and employing a gaseous mixture of O₂ gas and an unreactive gas (especially, Ar gas and N₂ gas) as a processing gas, it is possible to maintain a satisfactory film quality of the low-k film in the first and the second ashing processes. Further, by optimizing other processing conditions (e.g., the upper electrode electric power and the lower electrode electric power), the photoresist film can be more efficiently removed without inflicting damages on the low-k film.

A9. Optimum Processing Conditions in the Plasma Ashing Process

Although an example of the optimum processing conditions of the plasma ashing process performed on the object to be processed 200 illustrated in FIG. 2 has already been described, another example thereof will be described hereinafter. Further, the low-k film of the object to be processed 200 is Coral (registered trademark).

The following processing conditions, for example, apply to the first ashing process: a pressure in the chamber 102 at 20 mTorr; a gap of 40 mm between the upper electrode 121 and the susceptor 105; a high frequency electric power of 500 W applied to the upper electrode 121; a high frequency electric power of 0 W applied to the susceptor 105 (i.e., a high frequency electric power is not applied to the susceptor 105); a processing gas having a mixture of Ar and O₂ having a flow rate ratio of 400/100 sccm/sccm (a flow rate of Ar/a flow rate of O₂); and a processing time of 52 seconds.

The following processing conditions, for example, apply to the second ashing process: a pressure in the chamber 102 at 10 mTorr; a gap of 55 mm between the upper electrode 121 and the susceptor 105; a high frequency electric power of 500 W applied to the upper electrode 121; a high frequency electric power of 100 W applied to the susceptor 105; a processing gas having a mixture of N₂ and O₂ having a flow rate ratio of 60/60 sccm/sccm (a flow rate of N₂/a flow rate of O₂); and a processing time of 26 seconds.

By setting the above-described processing conditions, an upper via hole CD shift d0−d1t, an intermediate via hole CD shift d0-d1m and a bottom via hole CD shift d0−d1b were 8 nm, 3 nm and 0 nm, respectively, which are controlled to be smaller than or equal to 10 nm (see FIG. 4). In other words, in accordance with the plasma ashing process in accordance with this embodiment, the damage to the low-k film can be greatly reduced. Further, the etching stop film 210 is etched by 0 nm after the plasma ashing process is carried out, and a memory effect is suppressed.

Hereinafter, an example of optimum processing conditions of the plasma ashing process performed on the object to be processed 300 shown in FIG. 3 will be described. Further, a low-k film of the object to be processed 300 is Black Diamond (registered trademark).

The following processing conditions, for example, apply to the first ashing process: a pressure in the chamber 102 at 20 mTorr; a gap of 40 mm between the upper electrode 121 and the susceptor 105; a high frequency electric power of 500 W applied to the upper electrode 121; a high frequency electric power of 0 W applied to the susceptor 105 (i.e., a high frequency electric power is not applied to the susceptor 105); a processing gas having a mixture of Ar and O₂ having a flow rate ratio of 400/100 sccm/sccm (a flow rate of Ar/a flow rate of O₂); and a processing time of 33 seconds.

The following processing conditions, for example, apply to the second ashing process: a pressure in the chamber 102 at 10 mTorr; a gap of 55 mm between the upper electrode 121 and the susceptor 105; a high frequency electric power of 500 W applied to the upper electrode 121; a high frequency electric power of 100 W applied to the susceptor 105; a processing gas having a mixture of N₂ and O₂ having a flow rate ratio of 110/110 sccm/sccm (a flow rate of N₂/a flow rate of O₂); and a processing time of 20 seconds.

By setting the aforementioned processing conditions, in an area where trenches are densely formed, an upper trench CD shift d0−d1t, an intermediate trench CD shift d0−d1m and a bottom trench CD shift d0−d1b were 8 nm, 7 nm and 9 nm, respectively, which are controlled to be smaller than or equal to 10 nm (see FIG. 4). Meanwhile, in an area where trenches are sparsely formed, an upper trench CD shift (Δd1t=d0−d1t), an intermediate trench CD shift (Δd1m=d0−d1m) and a bottom trench CD shift (Δd1b=d0−d1b) were 2 nm, 7 nm and 2 nm, respectively, which are controlled to be smaller than or equal to 10 nm. As described above, in accordance with the plasma ashing process in accordance with this embodiment, the damage to the low-k film can be greatly reduced. Further, the etching stop film 210 is etched by 0 nm after the plasma ashing process is carried out, and a memory effect is suppressed.

B. Second Preferred Embodiment

Hereinafter, a second preferred embodiment of the present invention will be described with reference to the accompanying drawings. A plasma processing apparatus, structure of which is different from that of the plasma processing apparatus 101 in accordance with the first preferred embodiment can be used in a plasma processing which is performed on an object to be processed. Specifically, the plasma processing apparatus may have a structure in which a first high frequency electric power having a relatively high frequency of, e.g., 40 MHz, and a second high frequency electric power having a relatively low frequency of, e.g., 3.2 MHz, are superposedly applied to a lower electrode where an object to be processed is installed. In accordance with such plasma processing apparatus and a plasma processing method using the same, a plasma density and a bias voltage can be independently controlled. Further, since a high frequency electric power is applied only to the lower electrode without having to be applied to the upper electrode, the apparatus design can be simple.

However, in accordance with the plasma processing method in which two types of high frequency electric powers are superposedly applied to the lower electrode, in case a low-k film is etched by a fluorine-containing processing gas with a resist film as a mask and then the resist film is ashed by using an O-containing processing gas in the same chamber, a bias voltage is generated due to the first high frequency electric power even if the second high frequency electric power is set to be 0 W. In the ashing process, fluorine used in the etching process remains in the chamber, and such fluorine may be accelerated toward an under film of the low-k film and etch the under film. The following is a description on a plasma ashing processing method in which it is possible to ash a resist film while maintaining a satisfactory state of a low-k film and an under film thereof by using the plasma processing apparatus in which an electric power having two different types of frequencies is applied to a lower electrode.

B1. Plasma Processing Apparatus

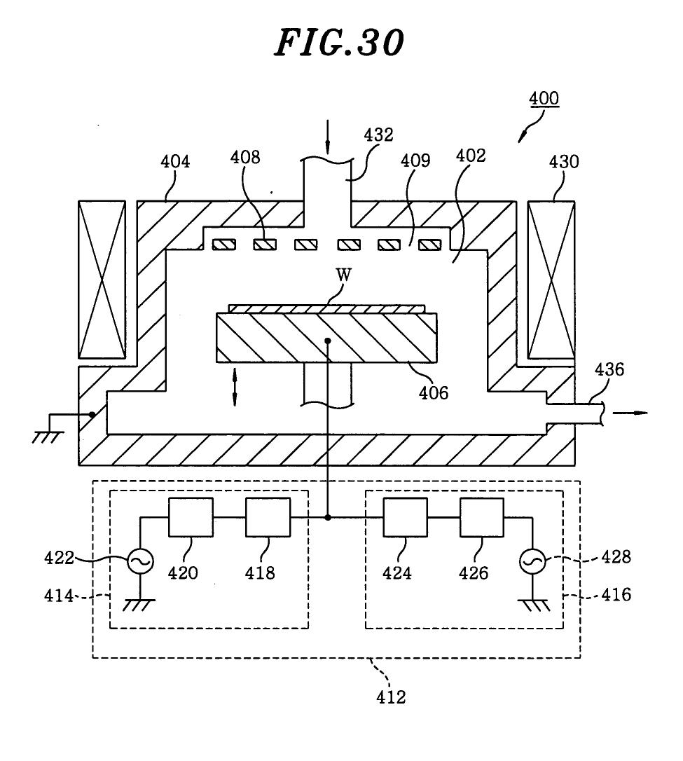

FIG. 30 illustrates a schematic structure of a plasma processing apparatus 400 in accordance with the second preferred embodiment. As shown in FIG. 30, the plasma processing apparatus 400 has an airtightly sealed chamber (a processing vessel) 404 that is grounded. A processing chamber 402 is formed inside the chamber 404. Provided in the processing chamber 402 is a vertically movable conductive lower electrode 406 serving as a mounting table for mounting thereon an object to be processed, e.g., a wafer W. The lower electrode 406 is maintained at a predetermined temperature by a temperature control mechanism (not shown), and a heat transfer gas from a heat transfer gas supply mechanism (not illustrated) is supplied between the wafer W and the lower electrode 406 at a predetermined pressure. An upper electrode 408 is formed opposedly to a mounting surface of the lower electrode 406.

Further, a gas inlet opening 432 connected to a gas supply source (not shown) is formed at an upper portion of the chamber 404, so that a predetermined processing gas can be introduced into the chamber 404. The processing gas introduced in the chamber 404 is introduced into the processing chamber 402 through a plurality of gas discharge openings 409 formed on the upper electrode 408. For example, CF₄ gas, CHF₃ gas, C₄F₈ gas, O₂ gas, He gas, Ar gas, N₂ gas and a gas having a mixture thereof are introduced into the processing chamber 402 as a processing gas.

Provided at a lower portion of the chamber 404 is a gas exhaust line 436 connected to a gas exhaust valve and a gas exhaust unit (not illustrated). An inner space of the chamber 404 is maintained under a certain vacuum level, e.g., 50 mTorr by evacuating via the gas exhaust line 436. Further, a magnet 430 is provided at a side portion of the chamber 404, and a magnetic field (a multi-pole magnetic field) for confining a plasma is formed near an inner wall of the processing chamber 402 by the magnet 430. A magnetic field strength is variable.

Connected to the lower electrode 406 is an electric power supply unit 412 for supplying a two frequency superposed electric power. The electric power supply unit 412 is composed of a first electric power supply unit 414 for supplying a first high frequency electric power of a first frequency and a second high frequency electric power supply unit 416 for supplying a second high frequency electric power of a second frequency which is lower than the first frequency.

The first electric power supply unit 414 includes a first filter 418, a first matching unit 420 and a first electric power supply 422 that are sequentially connected to lower electrode 406. The first filter 418 prevents electric power components of the second frequency from intruding into the first matching unit 420. The first matching unit 420 matches first high frequency electric power components. The first frequency is, e.g., 100 MHz.

The second electric power supply unit 416 includes a second filter 424, a second matching unit 426 and a second electric power supply 428 that are sequentially connected to lower electrode 406. The second filter 424 prevents electric power components of the first frequency from intruding into the second matching unit 426. The second matching unit 426 matches second high frequency electric power components. The second frequency is, e.g., 3.2 MHz.

In the plasma processing apparatus 400 configured as described above, a processing gas introduced into the chamber 404 is plasmatized due to two types of high frequency electric powers produced by the electric power supply unit 412 and a horizontal magnetic field formed by the magnet 430. Accordingly, an etching process and an ashing process can be performed on an object to be processed with an energy of a radical and ions accelerated by a magnetic bias voltage generated between the electrodes.

B2. Film Structure of an Object to be Processed

Like the plasma processing apparatus 101 in accordance with the first preferred embodiment, which is shown in FIG. 1, the above-described plasma processing apparatus 400 in accordance with the second preferred embodiment performs an etching process and an ashing process on, e.g., the objects to be processed 200 and 300 illustrated in FIGS. 2 and 3, respectively.

B3. Processing Conditions in a Plasma Processing

Hereinafter, a plasma etching process and a plasma ashing process, which are performed on, e.g., the object to be processed 200 illustrated in FIG. 2, by using the plasma processing apparatus 400, will be described.

Above all, the bottom anti-reflective coat 204 is etched with the patterned photoresist film 202 as a mask (a first etching process). Processing conditions of the first etching process are described as follows. For example, a pressure in the chamber 404 was controlled to be 50 mTorr. A high frequency (e.g., 100 MHz) electric power of 1000 W was applied from the first electric power supply 422 to the lower electrode 121. A high frequency (e.g., 3.2 MHz) electric power of 500 W was applied from the second electric power supply 428 to the lower electrode 406. Further, CF₄ was used as a processing gas.

Next, an etching of the low-k film 208 is performed with the patterned photoresist film 202 as a mask (a second etching process). The following processing conditions, for example, apply to the second etching process: a pressure in the chamber 404 at 35 mTorr; a high frequency (e.g., 100 MHz) electric power of 500 W applied from the first electric power supply 422 to the lower electrode 406; a high frequency (e.g., 3.2 MHz) electric power of 3000 W applied from the second electric power supply 428 to the lower electrode 406; and a processing gas having a mixture of CHF₃, Ar and N₂.

Thereafter, a so-called overetching process (a third etching process) is carried out to prevent a low-k material from remaining on a bottom portion of the via holes formed on the low-k film 208 during the second etching process. Processing conditions of the third etching process are described as follows. For example, a pressure in the chamber 102 was controlled to be 60 mTorr. A high frequency (e.g., 100 MHz) electric power of 300 W was applied from the first electric power supply 422 to the lower electrode 406, and a high frequency (e.g., 3.2 MHz) electric power of 2000 W was applied from the second electric power supply 428 to the lower electrode 406. Further, a gaseous mixture of C₄F₈, Ar and N₂ was used as a processing gas.

By performing the aforementioned first to third etching processes, via holes are formed on the low-k film 208. Further, if the first through the third etching processes are performed on the object to be processed 300, trenches are formed on the low-k film 308.

Then, the plasma ashing process is performed on the object to be processed 200 in order to remove the photoresist film 202 in the same chamber 404.

However, if the first through the third plasma etching processes are performed on the object to be processed 200 by using the plasma processing apparatus 400 in accordance with the second preferred embodiment, fluorine contained in a processing gas is adhered to an inner wall of the chamber 102 and gradually deposited as a fluorine polymer, as it did in the plasma processing apparatus 101 in accordance with the first preferred embodiment. In such state, if the plasma ashing process is carried out only to remove the photoresist film 202, the fluorine polymer deposited on the inner wall of the chamber 102 is redissociated, and the low-k film 208 or the etching stop film 210 as an under film, for example, is etched.

This is because fluorine in the chamber 404 is accelerated toward an object to be processed due to a bias voltage generated by the first high frequency electric power, the etching stop film 210 is cut by such fluorine during the ashing process of the resist film. To address this situations, in the plasma ashing processing method in accordance with this embodiment, a frequency of the first high frequency electric power is set to be, e.g., 100 MHz higher than a conventional frequency. Accordingly, the bias voltage decreases, thereby suppressing an etching of the etching stop film 210. Further, by optimizing other parameters of the processing conditions, the amount of etching of the etching stop film 210 by fluorine can be further reduced.

Moreover, in accordance with the plasma ashing processing method in accordance with this embodiment, a deterioration (e.g., an increase of a dielectric constant) of a film quality of the low-k film 208 can be prevented. As described above, a main reason for deteriorating the film quality of the low-k film 208 is that O contained in a processing gas becomes a radical, and the O radical changes a composition of a low-k material forming the low-k film 208. To address this problem, the plasma ashing method in accordance with this embodiment prevents a production of the O radical mainly by optimizing two processing conditions. First, an inner pressure of the chamber 102 is lowered. Second, a gaseous mixture of O₂ gas and an unreactive gas (especially, He gas) is employed as a processing gas. As a result, the film quality of the low-k film 208 can be maintained in a satisfactory state.

B4. Experiment of the Plasma Ashing Process

Experiment is conducted to find optimum ashing process conditions for maintaining satisfactory film quality of the low-k film 208 and for preventing the etching of the etching stop film 210 as an under film. To do so, the plasma ashing process is performed on the objects to be processed 200 and 300 illustrated in FIGS. 2 and 3, respectively in the plasma processing apparatus 400 in accordance with the embodiment. Further, each of the following experiments are performed to search for a desirable scope of the plasma ashing conditions, and each of the results shows a trend of changes in CD shifts Δd1t, Δd1m and Δd1b of the low-k film 208 and an etching amount ΔE of the etching stop film 210. In other words, each of the experiment results does not show a limit of the plasma ashing processing method in accordance with this embodiment. The optimal (or the optimal scope of) ashing processing conditions will be described later based on each of the experiment results.

In this experiment, a degree of damage to the low-k film by the plasma ashing process is judged based on a degree of erosion of the low-k film in soaking an object to be processed as a sample in a hydrofluoric (HF) acid. Such judging method is shown in the first preferred embodiment (see FIG. 4).

B5. Experiment 1: Dependence on an In-Chamber Pressure

First of all, an ashing process was carried out by using the object to be processed 200 (the low-k film 208 being Coral (registered trademark)) having the via hole illustrated in FIG. 2. In this experiment, the first high frequency electric power was set to be 100 MHz and 2500 W, and the second high frequency electric power was set to be 3.2 MHz and 0 W (i.e., the second electric power supply 428 does not output the second high frequency electric power). Further, an O₂ single gas was used as a processing gas. Moreover, a pressure of a cooling gas on a backside of a center portion of the object to be processed 200 was set to be 10 Torr, and a pressure of a cooling gas on a backside of an edge portion of the object to be processed 200 was set to be 50 Torr. Furthermore, a temperature of the upper electrode and that of the lower electrode in the chamber 404 were adjusted to 60° C. In addition, in order to completely remove the resist film 202, the ashing processing time was doubled as compared to when removing the resist film 202 (100% overashing) . Under such conditions, the CD shifts Δd1t, Δd1m and Δd1b of the low-k film 208 and the etching amount ΔE of the etching stop film 210 were measured by setting a pressure in the chamber 404 as a parameter (1 mTorr to 20 mTorr). A result of the experiment 1 is shown in Table 1.

TABLE 1

| | In-chamber pressure (mTorr) | | | | |
|---|---|---|---|---|---|
| | 20 | 10 | 5 | 3 | 1 |
| O₂ flow rate | 800 | 400 | 200 | 100 | 30 |
| Ashing time (sec) | 25 | 28 | 32 | 45 | 163 |
| Residence time | 110 | 110 | 110 | 132 | 147 |
| (nsec) | | | | | |
| Δd1t | 33 | 33 | 15 | 11 | 20 |
| Δd1m | 26 | 22 | 9 | 8 | 23 |
| Δd1b | 17 | 9 | 9 | 9 | 13 |
| ΔE | 21 | 31 | 33 | 37 | 64 |

The residence time shown in Table 1 indicates a length of time between an introduction of the processing gas (the O₂ single gas in this experiment) into the chamber 404 and an exhaust thereof from the chamber 404, i.e., a length of time that the processing gas has stayed in the chamber 404. In this experiment, the residence time was nearly constant within the range of 110 to 147 nsec. In accordance with a result of the experiment 1, when the pressure in the chamber 404 decreases in the range from 20 mTorr to 3 mTorr, the CD shifts Δd1t, Δd1m and Δd1b of the low-k film 208 are reduced. If the pressure in the chamber 404 is further lowered to 1 mTorr, the CD shift of the low-k film 208 bounce back and, further, the ashing time increases. In case the ashing time excessively increases, a pattern shape of the low-k film 208, especially, an opening thereof can be destroyed. Further, as the pressure in the chamber 404 increases, the etching amount ΔE of the etching stop film 210 decreases. A high flow rate of the processing gas is considered to be effective. A relationship between the flow rate of the processing gas and the etching amount ΔE of the etching stop film 210 will be described later.

In the experiment 1, since the pressure in the chamber 404 was set to be lower than a conventional pressure, a plasma may not be ignited. Therefore, a plasma ignition process was performed for three seconds before the ashing process. In the plasma ignition process, a pressure in the chamber 404 was set to be, e.g., 30 mTorr. Further, a first high frequency electric power was set to be 100 MHz and 300 W, and a second high frequency electric power was set to be 3.2 MHz and 0 W (i.e., the second electric power supply 428 does not output the second high frequency electric power). By performing the plasma ignition process, the plasma can be securely ignited and, then, the pressure in the chamber 404 is lowered in the ashing process. The plasma ignition process is properly performed in other experiments to be described later.

B6. Experiment 2: Dependence on Mixed Species of Processing Gas

Next, the same plasma ashing process performed in the experiment 1 was carried out while changing a processing gas from the O₂ single gas to a gaseous mixture of O₂ and He other conditions remaining the same as in experiment 1. A result thereof is shown in Table 2.

TABLE 2

| | In-chamber pressure | | |
|---|---|---|---|
| | (mTorr) | | |
| | 20 | 10 | 5 |
| O₂/He flow rate (sccm) | 50/800 | 50/350 | 50/150 |
| Ashing time (sec) | 32 | 25 | 29 |
| Residence time (nsec) | 103 | 110 | 110 |
| Δd1t | 17 | 12 | 5 |
| Δd1m | 5 | 0 | 7 |
| Δd1b | 2 | 2 | 5 |
| ΔE | 7 | 12 | 9 |

In this experiment, a pressure in the chamber 404 was controlled by fixing a flow rate of O₂ gas at 50 sccm while changing a flow rate of He gas. A residence time in the experiment 2 was nearly constant within the range of 103 to 110 nsec as in the experiment 1. In accordance with the result of the experiment 2, in case the pressure in the chamber 404 was smaller than or equal to 20 mTorr, especially, smaller than or equal to 10 mTorr, the CD shifts Δd1t, Δd1m and Δd1b of the low-k film 208 are reduced. Further, in the experiment 2, a decrease of the pressure in the chamber 404 hardly affects the ashing time (an ashing rate), which results from a constant flow rate of O₂ gas.

The etching amount ΔE of the etching stop film 210 can be greatly improved in the experiment 2 in comparison with the experiment 1. The etching amount ΔE of the etching stop film 210 can be reduced by employing a gaseous mixture of O₂ gas and unreactive gas, He gas or the like as a processing gas instead of employing the O₂ gas alone.

B7. Experiment 3: Dependence on a Processing Gas Flow Rate

In this experiment, the same plasma ashing process performed in the experiment 1 was carried out with the pressure in the chamber 404 fixed at 20 mTorr while varying a flow rate (a residence time) of the processing gas (the O₂ single gas) and putting othere conditions same as those in the experiment 1. A result of the experiment 3 is depicted in Table 3.

TABLE 3

| | O₂ flow rate (sccm) | | |
|---|---|---|---|
| | 50 | 400 | 800 |
| In-chamber pressure (mTorr) | 20 | 20 | 20 |
| Ashing time (sec) | 77 | 25 | 25 |
| Residence time (nsec) | 1758 | 200 | 110 |
| Δd1t | 33 | 34 | 33 |
| Δd1m | 26 | 24 | 26 |
| Δd1b | 16 | 16 | 17 |
| ΔE | 65 | 24 | 21 |

An increase in the flow rate of the processing gas (the O₂ single gas) hardly affects the CD shifts Δd1t, Δd1m and Δd1b of the low-k film 208. The etching amount ΔE of the etching stop film 210 can be improved by increasing the flow rate of the processing gas (the O₂ single gas). In consideration of the ashing time, it is preferable that the flow rate of the processing gas (the O₂ single gas) is greater than or equal to 400 sccm.

B8. Experiment 4: Dependence on a First High Frequency Electric Power

In this experiment, the same plasma ashing process performed in the experiment 1 was carried out with the pressure in the chamber 404 fixed at 50 mTorr while varying a first high frequency (100 MHz) electric power, other conditions remaining the same as in the experiment 1. A result of the experiment 4 is described in Table 4. Further, a second high frequency (3.2 MHz) electric power was set to be 0 W (i.e., the second electric power supply 428 does not output the second high frequency electric power).

TABLE 4

| | First high frequency | | |
|---|---|---|---|
| | electric power (W) | | |
| | 300 | 1000 | 2500 |
| Second high frequency electric | 0 | 0 | 0 |
| power (W) | | | |
| In-chamber pressure (mTorr) | 5 | 5 | 5 |
| Ashing time (sec) | 188 | 58 | 32 |
| Processing gas (O₂) flow rate | 200 | 200 | 200 |
| (sccm) | | | |
| Δd1t | 19 | 13 | 15 |
| Δd1m | 16 | 15 | 9 |
| Δd1b | 19 | 15 | 9 |
| ΔE | 22 | 30 | 33 |

As the first high frequency electric power applied to the lower electrode 406 increases, the CD shift (an average value of Δd1t, Δd1m and Δd1b) of the low-k film 208 decreases, and the ashing time is shortened (an ashing rate is improved). However, even if the first high frequency (100 MHz) electric power increases beyond 2500 W, a degree of improvement in the ashing rate decreases. Further, as the first high frequency (100 MHz) electric power increases, the etching amount ΔE of the etching stop film 210 increases. In accordance with such results, an optimal scope of the first high frequency (100 MHz) electric power is considered to range from 1000 W to 2500 W. Moreover, although a diameter of a wafer used in this experiment is 200 mm, the plasma processing apparatus 400 can accommodate a wafer having a diameter of up to 300 mm and a focus ring surrounding it having a diameter of 380 mm. Thus, an electric power of 1000 to 2500 W is converted into an electric power density of about 0.88 to 2.20 W/cm².

B9. Experiment 5: Dependence on a Second High Frequency Electric Power

In this experiment, the same plasma ashing process as that performed in the experiment 4 was carried out with the first high frequency (100 MHz) electric power fixed at 2500 W while varying the second high frequency (100 MHz) electric power, other conditions remaining the same as in the experiment 4. A result of the experiment 5 is described in Table 5. Further, in this experiment, the pressure in the chamber 404 was maintained at 20 mTorr, and a gaseous mixture (having a constant flow rate) of O₂ gas and Ar gas was used as a processing gas.

TABLE 5

Second high frequency
electric power (W)

| | 0 | 500 |
|---|---|---|
| First high frequency electric power | 2500 | 2500 |
| (W) | | |
| In-chamber pressure (mTorr) | 20 | 20 |
| Ashing time (sec) | 29 | 22 |
| Processing gas (O₂/Ar) flow rate | 400/400 | 400/400 |
| (sccm) | | |
| Δd1t | 23 | 12 |
| Δd1m | 16 | 17 |
| Δd1b | 11 | 14 |
| ΔE | 26 | 32 |

In case the second high frequency (3.2 MHz) electric power of 500 W (0.44 W/cm²) is applied to the lower electrode 406, the CD shift (an average value of Δd1t, Δd1m and Δd1b) of the low-k film 208 decreases and the ashing time is shortened (an ashing rate is improved) in comparison with a case the second high frequency (3.2 MHz) electric power is not applied thereto. In this case, however, the etching amount ΔE of the etching stop film 210 increases. In accordance with such results, an optimal scope of the second high frequency (3.2 MHz) electric power is determined to range from 0 W to 500 W (0 to 0.44 W/cm²).

B10. Experiment 6: Dependence on a Mixing Ratio of a Processing Gas

In this experiment, the same plasma ashing process performed in the experiment 1 was carried out with a pressure in the chamber 404 at 20 mTorr, while varying a flow rate ratio of O₂ gas to Ar gas, other conditions remaining the same as in the conditions of the experiment 1. A result of the experiment 6 is illustrated in Table 6.

TABLE 6

| | O₂/Ar flow rate (sccm), | | | |
|---|---|---|---|---|
| | (Ar flow rate ratio (%)) | | | |
| | 800/0, | 400/400, | 200/600, | 100/700, |
| | (0) | (50) | (75) | (87.5) |
| In-chamber | 20 | 20 | 20 | 20 |
| pressure | | | | |
| (mTorr) | | | | |
| Ashing time | 25 | 29 | 39 | 55 |
| (sec) | | | | |
| Ashing rate | 13431 Å | 11497 Å | 8653 Å | 6104 Å |
| | /min ± 9.2% | /min ± 9.1% | /min ± 9.7% | /min ± 7.8% |
| Δd1t | 33 | 23 | 22 | 14 |
| Δd1m | 26 | 16 | 15 | 12 |
| Δd1b | 17 | 11 | 15 | 10 |
| ΔE | 21 | 26 | 33 | 32 |

If a ratio of Ar gas to O₂ gas in the processing gas increases, the CD shift (an average value of Δd1t, Δd1m and Δd1b) of the low-k film 208 decreases, whereas the ashing rate decreases and the etching amount ΔE of the etching stop film 210 increases. Accordingly, it is appropriate that the ratio of Ar gas in the processing gas (a flow rate of Ar gas/a total flow rate of the processing gas) ranges from 75% to 87.5%. Further, instead of the object to be processed illustrated in FIG. 2, a PR blanket sample in which a photoresist material is coated on an entire surface of a wafer was used for measuring the ashing rate. In accordance with the measurement result, a desirable in-surface uniformity can be obtained regardless of a mixing ratio of Ar gas.

B11. Experiment 7: Dependence on Mixed Species of Processing Gas

The result of the experiment 6 provides a conclusion that it is preferable to use the gaseous mixture of O₂ gas and Ar gas as a processing gas. In case only O₂ gas is used as a processing gas, a high ashing rate is obtained, whereas the CD shift (an average value of Δd1t, Δd1m and Δd1b) of the low-k film 208 increases. By adding Ar gas or the like to O₂ gas, O₂ gas in the processing gas is diluted, thereby relieving damage to the low-k film 208 by O₂ gas. However, it is preferable to maintain the high ashing rate in terms of a throughput. Therefore, an experiment was performed to search for gaseous mixture species having the most similar ashing rate to that when the O₂ gas is a single constituent of the processing gas. Specifically, processing gases (gaseous mixtures) were generated by mixing O₂ gas with each of Ar gas, N₂ gas, CO gas and He gas at equal flow rate ratios and then a PR blanket sample was ashed by using each of the processing gases (the gaseous mixtures and the O₂ single gas) to thereby measure ashing rates thereof. A result of the experiment 7 is described in Table 7. Further, in this experiment, other process conditions except for gas species contained in the processing gas are equal to those in the experiment 6.

TABLE 7

| | Processing gas | | | | |
|---|---|---|---|---|---|
| | O₂ (only) | O₂/He | O₂/Ar | O₂/N₂ | O₂/CO |
| Flow rate (mTorr) | 800 | 100/700 | 100/700 | 100/700 | 100/700 |
| Ashing rate | 13431 Å/min ± 9.2% | 8993 Å/min ± 8.6% | 6105 Å/min ± 7.8% | 5065 Å/min ± 8.5% | 4809 Å/min ± 8.6% |

The ashing rate obtained by using the gaseous mixture of O₂ gas and He gas as a processing gas is most similar to that obtained by using the O₂ single gas as a processing gas, and the ashing rates become lower in the order of Ar gas, N₂ gas and CO gas. In accordance with the measurement result, the gaseous mixture of O₂ gas and He gas is determined to be the most desirable processing gas. Further, as for the in-surface uniformity, a satisfactory result was obtained regardless of the processing gases.

In terms of the ashing rate, He gas is the most suitable gas to be mixed with O₂ gas as described above. In order to check other points of view, an examination on a superiority of He gas was carried out.

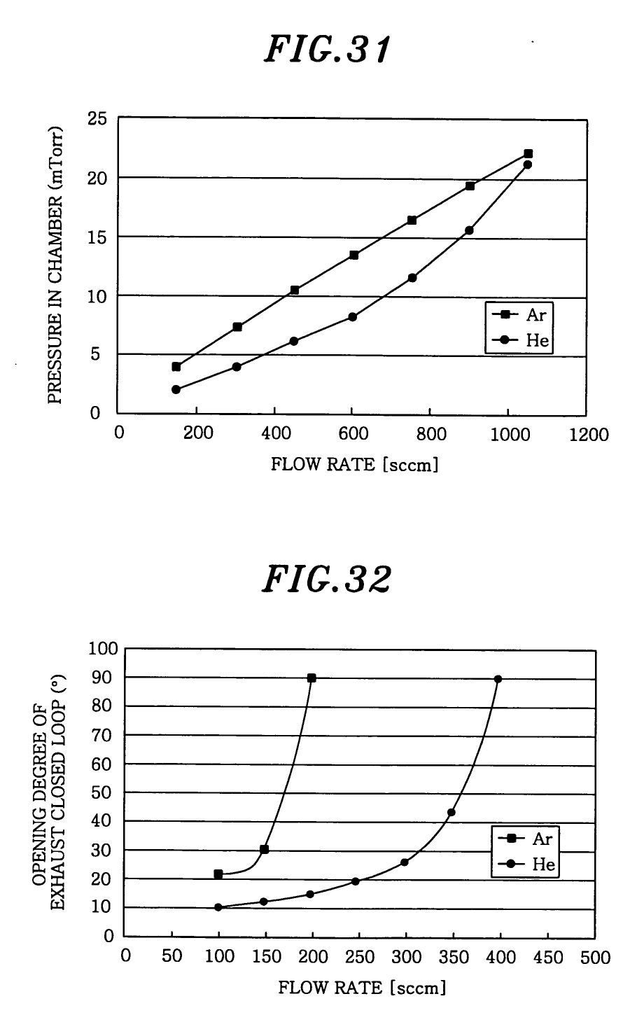

First of all, in the plasma processing apparatus 400, a pressure in the chamber 404 was measured while varying a flow rate of a gas introduced into the chamber 404 with a gas exhaust valve entirely opened. A measurement result is shown in FIG. 31. Herein, He gas and Ar gas, second to only He gas in ashing rate, are introduced into the chamber 404, for comparison.

As described above, in order to decrease the CD shifts Δd1t, Δd1m and Δd1b of the low-k film 208, it is preferable to lower the pressure in the chamber 404 (see the experiments 1 and 2) and increase a ratio of the gaseous mixture to O₂ gas in the processing gas (see the experiment 6). Moreover, as the flow rate of O₂ gas in the processing gas increases, the etching amount ΔE of the etching stop film 210 decreases (see the experiment 3).

Referring to FIG. 31, in case of Ar gas, a flow rate thereof is limited to about 200 sccm in order to maintain the pressure in the chamber 404 at 5 mTorr. If Ar gas having a flow rate which is greater than or equal to 200 sccm is introduced into the chamber 404, the pressure in the chamber 404 increases. Meanwhile, in case of He gas, the pressure in the chamber 404 can be maintained at 5 mTorr with a flow rate of about 400 sccm. In other words, He gas is more desirable than Ar gas in order to introduce more processing gases into the chamber 404.

Thereafter, in the plasma processing apparatus 400, a relationship between an opening degree of a gas exhaust valve (not shown) for maintaining the pressure in the chamber 404 at 5 mTorr and a gas flow rate that can be introduced into the chamber 404 was examined. The relationship therebetween is illustrated in FIG. 32. Herein, by employing He gas and Ar gas as a gas to be introduced into the chamber 404, characteristics of both gases were compared. Further, in FIG. 32, an opening degree of 0° in a gas exhaust valve indicates a completely closed state, and an opening degree of 90° represents a completely open state.

In case the plasma processing apparatus 400 is used in actual processes of a semiconductor device, an opening degree of the gas exhaust valve is generally controlled less than or equal to 25° in order to precisely control the pressure in the chamber 404. As can be seen from the measurement result illustrated in FIG. 32, in case an opening degree of the gas exhaust valve is 20°, He gas can be introduced into the chamber 404 with a flow rate of about 250 sccm, whereas a flow rate of Ar gas is limited to about 100 sccm. In other words, even if Ar gas having a flow rate greater than or equal to 100 sccm is introduced into the chamber 404, an opening degree of the exhaust valve exceeds its upper limit of 25°, resulting in a difficult pressure control in the chamber 404.

As can be seen from the measurement results illustrated in FIGS. 31 and 32, it is effective to employ He gas as a gas to be mixed with O₂ gas in order to slightly suppress the CD shifts Δd1t, Δd1m and Δd1b of the low-k film 208 and the etching amount ΔE of the etching stop film 210 in the plasma ashing process.

As clearly can be seen from the results of the experiments 1 to 7, it is possible to efficiently remove the photoresist film 202 while slightly suppressing the CD shifts Δd1t, Δd1m and Δd1b of the low-k film 208 and the etching amount ΔE of the etching stop film 210 by lowering a pressure in the chamber 404 (see the experiments 1 and 2); increasing a flow rate of a processing gas (see the experiment 3); controlling the first high frequency (100 MHz) electric power to range from 1000 W to 2500 W (see the experiment 4); and controlling the second high frequency (3.2 MHz) electric power to range from 0 W to 500 W (see the experiment 5). Further, it is more preferable to increase a mixing ratio of He gas by employing a gaseous mixture of O₂ gas and He gas (see the experiments 6 and 7).

B12. Application of a Hybrid-Ashing

However, as described above, when the plasma etching process is performed on the object to be processed in the plasma processing apparatus 400, fluorine contained in a processing gas is adhered to an inner wall of the chamber 404 and gradually deposited as a fluorine polymer. Then, during an ashing process of the resist film 202 successively performed after the etching process, the etching stop film 210 is cut. This is because the fluorine polymer deposited on the inner wall of the chamber 102 during the etching process is redissociated, and such generated fluorine is accelerated toward an object to be processed due to a bias voltage applied to the object to be processed and cut the etching stop film 210.

To address this situation, it is effective to lower the bias voltage applied to the object to be processed. Further, the bias voltage can be lowered by setting a frequency of the first high frequency electric power to be, e.g., 100 MHz, which is higher than a conventional frequency. A frequency of the first high frequency electric power was set to be 100 MHz in the experiments 1 to 6, and an effect thereof was proved.

However, even though the frequency of the first high frequency electric power is set to be 100 MHz, it is hardly possible to set the bias voltage to be 0 V. Accordingly, a large amount of the etching stop film 210 may be cut depending on conditions in the chamber 404 or structures of the object to be processed. In such case, it is preferable to perform a process for removing fluorine deposited on the inner wall of the chamber 404 before carrying out the ashing process for removing the resist film 202 with the bias voltage set as low as possible.

After the plasma etching process is performed on the object to be processed, the ashing process for removing the resist film may be carried out by setting the processing conditions as needed in accordance with the results of the experiments 1 to 7. Further, if necessary, a process for cleaning an interior of the chamber 404 (a first ashing process) can be performed between the plasma etching process performed on the object to be processed and the ashing process for removing the resist film 202 (a second ashing process). The latter ashing process of two steps is the aforementioned so-called hybrid-ashing. Processing conditions of the second ashing process can be set as needed based on the results obtained from the experiments 1 to 7. The first ashing process needs to employ processing conditions capable of efficiently removing fluorine deposited on the inner wall of the chamber 404 even if an ashing rate is low. Further, as in the second ashing process, it is preferable to employ processing conditions capable of reducing the CD shifts Δd1t, Δd1m and Δd1b of the low-k film 208 and the etching amount ΔE of the etching stop film 210. Hereinafter, optimal (or an optimal scope of) ashing processing conditions in which the bias voltage is set even lower by decreasing the first high frequency electric power in the first ashing process of the hybrid ashing will be described with reference to experiment results.

B13. Experiment 8: Dependence on an In-Chamber Pressure

First of all, the first ashing process was carried out by using the object to be processed 200 (the low-k film 208 being Coral (registered trademark)) having the via hole illustrated in FIG. 2. In this experiment, the first high frequency electric power was set to be 100 MHz and 300 W, and the second high frequency electric power was set to be 3.2 MHz and 0 W (i.e., the second electric power supply 428 does not output the second high frequency electric power). Further, a gaseous mixture of O₂ gas and Ar gas was used as a processing gas. Moreover, a pressure of a cooling gas on a backside of a center portion of the object to be processed 200 was set to be 10 Torr, and a pressure of a cooling gas on a backside of an edge portion of the object to be processed 200 was set to be 50 Torr. Furthermore, a temperature of the upper electrode and that of the lower electrode in the chamber 404 were adjusted to 60° C. Under such conditions, the CD shifts Δd1t, Δd1m and Δd1b of the low-k film 2087 and the etching amount ΔE of the etching stop film 210 were measured by setting a pressure in the chamber 404 as a parameter (5 mTorr to 20 mTorr). A result of the experiment 8 is shown in Table 8.

TABLE 8

| | In-chamber pressure (mTorr) | | |
|---|---|---|---|
| | 20 | 10 | 5 |
| O₂/Ar flow rate (sccm) | 100/700 | 100/300 | 100/0 |
| Ashing time (sec) | 76 | 93 | 36 |
| Δd1t | 32 | 22 | 20 |
| Δd1m | 2 | 5 | 2 |
| Δd1b | 0 | 3 | 7 |
| ΔE | 2 | 9 | 2 |

In accordance with the result of the experiment 8, in case the pressure in the chamber 404 is smaller than (or equal to) 20 mTorr, the CD shifts Δd1t, Δd1m and Δd1b of the low-k film 2087 and the etching amount ΔE of the etching stop film 210 are reduced. Especially, in order to more slightly suppress the CD shifts Δd1t, Δd1m and Δd1b of the low-k film 2087 and the etching amount ΔE of the etching stop film 210, it is preferable to set the pressure in the chamber 404 to be 5 mTorr. Further, in this experiment, a flow rate ratio between O₂ gas and Ar gas is changed to control the pressure in the chamber 404. In this case, a flow rate of O₂ gas is fixed at 100 sccm in order to maintain an ashing rate.

However, in an experiment 9, the pressure in the chamber 404 is set to be lower than a conventional pressure, so that a plasma may not be ignited. Therefore, a plasma ignition process was performed for three seconds before performing the first ashing process. In the plasma ignition process, the pressure in the chamber 404 was set to be, e.g., 30 mTorr. The first high frequency electric power was set to be 100 MHz and 300 W, and the second high frequency electric power was set to be 3.2 MHz and 0 W (i.e., the second electric power supply 428 does not output the second high frequency electric power). Due to the plasma ignition process, the plasma is ignited without a failure and, then, the pressure in the chamber 404 can be lowered in the ashing process. The plasma ignition process is properly performed in other experiments to be described later.

B14. Experiment 9: Dependence of a Processing Gas Flow Rate

In this experiment, the same plasma ashing process performed in the experiment 8 was carried out with the pressure in the chamber 404 fixed at 5 mTorr while varying a flow rate (a residence time) of a processing gas (the O₂ single gas), other conditions remaining the same as in the experiment 8. A result of the experiment 9 is shown in Table 9.

TABLE 9

O₂ flow rate (sccm)

| | 5 | 200 |
|---|---|---|
| Pressure in a chamber (mTorr) | 5 | 5 |
| Ashing time (sec) | 358 | 188 |
| Δd1t | 37 | 19 |
| Δd1m | 33 | 16 |
| Δd1b | 27 | 19 |
| ΔE | 19 | 22 |

An increase or a decrease in the flow rate of the processing gas (the O₂ single gas) does not greatly affect the etching amount ΔE of the etching stop film 210. Meanwhile, the CD shifts Δd1t, Δd1m and Δd1b of the low-k film 208 can be improved by increasing a flow rate of the processing gas (the O₂ single gas). Thus, as the flow rate of the processing gas increases, a desirable process result can be obtained. However, in consideration of a performance limit of a gas supply/exhaust of the plasma processing apparatus 400, the flow rate of the processing gas is preferably controlled within the range of, e.g., 100 to 20 sccm in case the pressure in the chamber 404 is controlled to be 5 mTorr; 400 to 800 sccm in case the pressure in the chamber 404 is controlled to be 20 mTorr; and 800 to 1600 sccm in case the pressure in the chamber 404 is controlled to be 40 mTorr to completely clean the interior of the chamber 404.

B15. Experiment 10: Dependence on a First High Frequency Electric Power

In this experiment, a PR blanket sample and a sample in which a SiO₂ film is formed on an entire surface of a wafer (hereinafter, referred to as ‘SiO₂ blanket sample’) were used. As described above, the etching stop film 210, i.e., an under film of the low-k film 208, of the object to be processed 200 is made of an SiC material. Herein, however, the SiO₂ blanket sample was used as a substitution in order to check a trend of an ashing rate of an SiC film.

Above all, an ashing process was performed by using the PR blanket sample. In this experiment, a pressure in the chamber 404 was fixed at 20 mTorr, and the second high frequency electric power was set to be 3.2 MHz and 0 W (i.e., the second electric power supply 428 does not output the second high frequency electric power). Further, a gaseous mixture of O₂ gas (having a flow rate of 100 sccm) and Ar gas (having a flow rate of 400 sccm) was used as a processing gas. Moreover, a pressure of a cooling gas on a backside of a center portion of the PR blanket sample was set to be 10 Torr, and a pressure of a cooling gas on a backside of an edge portion of the PR blanket sample was set to be 50 Torr. Furthermore, a temperature of the upper electrode and that of the lower electrode in the chamber 404 were respectively adjusted to 60° C. Under such conditions, an ashing rate of the resist film of the PR blanket was measured by setting an electric power level of the first high frequency (100 MHz) electric power as a parameter. However, this experiment was carried out in a state that the chamber 404 is clean, i.e., there is no deposit on the inner wall of the chamber 404.

Next, an ashing process was performed by using the SiO₂ blanket sample. The processing conditions of the ashing process using the PR blanket sample were equally used in this experiment. Further, an etching rate of the SiO₂ film of the SiO₂ blanket sample was measured by setting the electric power level of the first high frequency (100 MHz) electric power as a parameter. However, before such ashing process is performed, an etching process for forming via holes was performed on the SiO₂ blanket sample. Therefore, this ashing process was carried out in a state that there are deposits on the inner wall of the chamber 404.

Results of the experiment using the PR blanket sample and that using the SiO₂ blanket sample are described in Table 10.

TABLE 10

| | First high frequency electric power (W) | | | |
|---|---|---|---|---|
| | 200 | 300 | 500 | 2500 |
| Second high | 0 | 0 | 0 | 0 |
| frequency | | | | |
| electric power | | | | |
| (W) | | | | |
| In-chamber | 20 | 20 | 20 | 20 |
| pressure | | | | |
| (mTorr) | | | | |
| Resist film | 796 Å | 1327 Å | — | 7666 Å |
| ashing rate | /min ± 9.4% | /min ± 8.2% | | /min ± 10.6% |
| Chamber | 60 | 60 | 50 | 40 |
| deposit | | | | |
| removing time | | | | |
| (sec) | | | | |
| SiO₂ etching | 8.4 Å | 12.2 Å | 26.2 Å | 107.0 Å |
| rate (etching | /min | /min | /min | /min |
| amount during | (8.4 Å) | (12.2 Å) | (21.8 Å) | (71.3 Å) |
| deposit | | | | |
| removing time) | | | | |

In accordance with the experiment result, as the first high frequency (100 MHz) electric power applied to the lower electrode 406 increases, an ashing rate of the resist film also increases. That is, in order to shorten a time required for removing deposits in the chamber 404, the first high frequency (100 MHz) electric power needs to be increased. However, an increase in the first frequency (100 MHz) electric power applied to the lower electrode 406 increases the etching rate of the SiO₂ film. As described above, the SiO₂ film is used to substitute the etching stop film 210 as an under film of the low-k film 208 in the experiment. If a condition in which the ashing rate of the SiO₂ film increases is employed, the etching amount ΔE of the etching stop film 210 during the ashing process increases.

The ‘chamber-deposit-removing-time’ illustrated in Table 10 indicates a standard of time required for completely removing deposits on the inner wall of the chamber 404. For example, in case the first high frequency (100 MHz) electric power is 2500 W, 40 seconds are required to completely remove the deposits in the chamber 404. In such condition, an etching rate of the SiO₂ film is 107.0 Å/min and. Thus, when the deposits in the chamber 404 are completely removed, the SiO₂ film is cut by 71.3 Å. Meanwhile, in case the first high frequency (100 MHz) electric power is 300 W, the SiO₂ film is cut by 12.2 Å, when the deposits in the chamber 404 are completely removed. Therefore, it is desirable that the first high frequency (100 MHz) electric power is controlled within the range of 200 to 500 W (0.18 to 0.44 W/cm²) with 300 W (0.26 W/cm²) as a center in order to etch the under film of the low-k film 208 as slightly as possible in the first ashing process.

B16. Experiment 11: Dependence on a Second High Frequency Electric Power

In this experiment, the pressure in the chamber was fixed at 5 mTorr. Further, the first high frequency (100 MHz) electric power was set to be 100 MHz and 300 W, and the O₂ single gas (having a flow rate of 200 sccm) was used as a processing gas. Moreover, a pressure of a cooling gas on a backside of a center portion of the object to be processed 200 was set to be 10 Torr, and a pressure of a cooling gas on a backside of an edge portion of the object to be processed 200 was set to be 50 Torr. Furthermore, a temperature of the upper electrode and that of the lower electrode in the chamber 404 were respectively adjusted to 60° C. Under such conditions, the CD shifts Δd1t, Δd1m and Δd1b of the low-k film 2087 and the etching amount ΔE of the etching stop film 210 were measured by setting the second high frequency (3.2 MHz) electric power as a parameter. A result of the experiment 11 is shown in Table 11.

TABLE 11

Second high frequency electric
power (W)

| | 0 | 200 |
|---|---|---|
| First high frequency | 300 | 300 |
| electric power (W) | | |
| In-chamber pressure | 5 | 55 |
| (mTorr) | | |
| Ashing time (sec) | 188 | 76 |
| Processing gas (O₂) | 200 | 200 |
| flow rate (sccm) | | |
| Δd1t | 19 | 12 |
| Δd1m | 16 | 17 |
| Δd1b | 19 | 10 |
| ΔE | 22 | 24 |

As can be seen from the experiment result, the CD shifts Δd1t, Δd1m and Δd1b of the low-k film 208 and the etching amount ΔE of the etching stop film 210 can be reduced only by applying the first high frequency (100 MHz) electric power to the lower electrode 406 without applying the second frequency (3.2 MHz) electric power thereto in the first ashing process. However, as illustrated in Table 11, even if the second high (3.2 MHz) electric power is applied to the lower electrode 406, it is not shown a great difference in the CD shifts Δd1t, Δd1m and Δd1b of the low-k film 208 and the etching amount ΔE of the etching stop film 210. Nonetheless, there shows an improvement in the CD shifts ≢d1t, Δd1m and Δd1b of the low-k film 208. Further, the ashing time is shortened. Therefore, it is desirable that the second high frequency (3.2 MHz) electric power ranges from 0 to 200 W in the first ashing process.

B17. Optimum Processing Conditions in the Plasma Ashing Process

Optimal processing conditions obtained from the results of the experiments 1 to 11 are described in Table 12.

TABLE 12

| | First ashing | Second ashing |
|---|---|---|
| | process | process |
| In-chamber pressure (mTorr) | 5˜20 | 5˜20 |
| Processing gas flow rate | 100˜200 | 100˜150 |
| (sccm) | (220˜110) | (220˜147) |
| (residence time (nsec)) | @5 mTorr | @5 mTorr |
| | — | 400˜800 |
| | | (200˜110) |
| | | @20 mTorr |
| O₂ added gas | He or Ar | He or Ar |
| (processing gas) | | |
| Additive gas rate (%) | 75.0˜87.5 | 75.0˜87.5 |
| (over total flow rate) | @ 20 mTorr | @ 20 mTorr |
| First high frequency | 200˜500 W | 1000˜2500 W |
| (100 MHz) electric power | (0.18˜0.44 | (0.88˜2.20 |
| | W/cm²) | W/cm²) |
| Second high frequency | under 200 W | under 500 W |
| (3.2 MHz) electric power | (under 0.18 | (under 0.44 |
| | W/cm²) | W/cm²) |

Further, it is preferable that outputs (on/off) of the first high frequency (100 MHz) electric power and the second high frequency (3.2 MHz) electric power and a relationship between electric power levels in the etching process and the first and the second ashing processes are subject to one of the three patterns to be described in Table 13.

TABLE 13

| | |
|---|---|
| Etching | Ashing process |

| | | |
|---|---|---|
| process | First | Second |

| | | | | |
|---|---|---|---|---|
| 1 | First high | ON | ON | ON (high electric |
| | frequency electric | | | power than the |
| | power | | | first process) |
| | Second high | ON | OFF | OFF |
| | frequency electric | | | |
| | power | | | |
| 2 | First high | ON | ON | ON (high electric |
| | frequency electric | | | power than the |
| | power | | | first process) |
| | Second high | ON | OFF | ON |
| | frequency electric | | | |
| | power | | | |
| 3 | First high | ON | ON | ON (high electric |
| | frequency electric | | | power than the |
| | power | | | first process) |
| | Second high | ON | ON | ON (high electric |
| | frequency electric | | | power than the |
| | power | | | first process) |

By selecting desirable exemplary processing conditions among the optimal scope of the processing conditions illustrated in Tables 12 and 13 and performing the plasma ashing process on the object to be processed 200 shown in FIG. 2 under such processing conditions, effects on the CD shifts Δd1t, Δd1m and Δd1b of the low-k film 2087 and the etching amount ΔE of the etching stop film 210 were examined. A result thereof is shown in Table 14. Two exemplary processing conditions described in Table 14 have a difference in processing gas types. In other words, an O₂ single gas and a gaseous mixture of O₂ gas and He gas were used in respective cases.

TABLE 14

| | | Condition | Condition |
|---|---|---|---|
| | | 1 | 2 |
| First ashing | In-chamber pressure | 5 | 5 |
| process | (mTorr) | | |
| | First high frequency | 300 | 300 |
| | electric power (W) | | |
| | Second high frequency | 0 | 0 |
| | electric power (W) | | |
| | Processing gas | O₂ | O₂/He |
| | Processing gas flow | 100 | 50/150 |
| | rate (sccm) | | |
| | Ashing time (sec) | 36 | 37 |
| Second ashing | In-chamber pressure | 5 | 5 |
| process | (mTorr) | | |
| | First high frequency | 2500 | 2500 |
| | electric power (W) | | |
| | Second high frequency | 0 | 0 |
| | electric power (W) | | |
| | Processing gas | O₂ | O₂/He |
| | Processing gas flow | 100 | 50/150 |
| | rate (sccm) | | |
| | Ashing time (sec) | 17 | 20 |
| | Δd1t | 10 | 5 |
| | Δd1m | 0 | 10 |
| | Δd1b | 8 | 7 |
| | ΔE | 9 | 7 |

By setting the aforementioned processing condition 1 illustrated in Table 14, an upper via hole CD shift Δd1t, an intermediate via hole CD shift Δd1m and a bottom via hole CD shift Δd1b were 10 m, 0 nm and 8 nm, respectively, and the etching stop film 210 was etched by 9 nm, which are controlled to be smaller than or equal to 10 nm. Further, by setting the above-described processing condition 2, an upper via hole CD shift Δd1t, an intermediate via hole CD shift Δd1m and a bottom via hole CD shift Δd1b were 5 m, 10 nm and 7 nm, respectively, and the etching stop film 210 was cut by 7 nm, which are controlled to be smaller than or equal to 10 nm. In accordance with the plasma ashing process in accordance with this embodiment, the damage to the low-k film and the under film of the low-k film can be greatly reduced.

The present invention is applicable to a manufacturing method of a semiconductor device such as a transistor or the like.

In accordance with the present invention, the amount of O radical generated in a processing vessel is suppressed. As a result, it is possible to avoid a deterioration of a low dielectric constant film of an object to be processed. Further, in accordance with the present invention, an ashing rate of a resist film can be maintained at an appropriate level.

While the invention has been shown and described with respect to the preferred embodiments, it will be understood by those skilled in the art that various changes and modifications may be made without departing from the spirit and scope of the invention as defined in the following claims.

1. A plasma ashing method of an object to be processed, for removing a resist film therefrom in a processing vessel after etching a part of a low dielectric constant film with the resist film having a pattern thereon as a mask in the processing vessel, the plasma ashing method comprising the steps of:
a first ashing process for removing deposits off an inner wall of the processing vessel by using a first processing gas including at least O₂ gas while controlling the pressure in the processing vessel to be smaller than or equal to 20 mTorr; and
a second ashing process for removing the resist film by using a second processing gas including at least O₂ gas.

2. The plasma ashing method of claim 1, wherein, in the second ashing process, the pressure in the processing vessel is controlled to be smaller than or equal to 20 mTorr.

3. The plasma ashing method of claim 1, wherein the first processing gas includes the O₂ gas and a first unreactive gas.

4. The plasma ashing method of claim 3, wherein the flow rate of the first unreactive gas included in the first processing gas occupies 50 to 90% of the total flow rate of the O₂ gas and the first unreactive gas included in the first processing gas.

5. The plasma ashing method of claim 3, wherein the first unreactive gas is one selected from the group consisting of Ar gas, N₂ gas, He gas and Xe gas.

6. The plasma ashing method of claim 1, wherein the second processing gas includes the O₂ gas and a second unreactive gas.

7. The plasma ashing method of claim 6, wherein the flow rate of the second unreactive gas included in the second processing gas occupies 50 to 90% of the total flow rate of the O₂ gas and a second unreactive gas included in the second processing gas.

8. The plasma ashing method of claim 6, wherein the second unreactive gas is selected from the group consisting of Ar gas, N₂ gas, He gas and Xe gas.

9. A plasma ashing method of an object to be processed, for removing a resist film therefrom in a processing vessel after etching a part of a low dielectric constant film with the resist film having a pattern thereon as a mask in the processing vessel, the plasma ashing method comprising the steps of:
a first ashing process for removing deposits off an inner wall of the processing vessel by using a first processing gas including O₂ gas and a first unreactive gas; and
a second ashing process for removing the resist film by using a second processing gas including O₂ gas and a second unreactive gas.

10. The plasma ashing method of claim 9, wherein, in the first ashing process, the pressure in the processing vessel is controlled to be smaller than or equal to 20 mTorr.

11. The plasma ashing method of claim 9, wherein in the second ashing process, the pressure in the processing vessel is controlled to be smaller than or equal to 20 mTorr.

12. The plasma ashing method of claim 9, wherein the flow rate of the first unreactive gas included in the first processing gas occupies 50 to 90% of the total flow rate of the O₂ gas and the first unreactive gas included in the first processing gas.

13. The plasma ashing method of claim 9, wherein the first unreactive gas is one selected from the group consisting of Ar gas, N₂ gas, He gas or Xe gas.

14. The plasma ashing method of claim 9, wherein the flow rate of the second unreactive gas included in the second processing gas occupies 50 to 90% of the total flow rate of the O₂ gas and the second unreactive gas.

15. The plasma ashing method of claim 9, wherein the second unreactive gas is one selected from the group consisting of Ar gas, N₂ gas, He gas and Xe gas.

16. The plasma ashing method of claim 1, wherein, in the first ashing process, no electric power is applied to the object to be processed.

17. The plasma ashing method of claim 1, wherein, in the first ashing process, an electric power applied to the object to be processed is smaller than or equal to 0.19 W/cm².

18. The plasma ashing method of claim 1, wherein, in the second ashing process, an electric power applied to the object to be processed is greater than or equal to 0.19 W/cm².

19. A plasma ashing method of an object to be processed, for removing a resist film therefrom in a processing vessel after etching a part of a low dielectric constant film with the resist film having a pattern thereon as a mask in the processing vessel, the plasma ashing method comprising the step of:
an ashing process for removing the resist film by using a processing gas including at least O₂ gas while controlling the pressure in the processing vessel to be smaller than or equal to 20 mTorr.

20. The plasma ashing method of claim 19, wherein, in the ashing process, the pressure in the processing vessel is controlled to be greater than or equal to 3 mTorr.

21. The plasma ashing method of claim 19, wherein the processing gas is the O₂ gas.

22. The plasma ashing method of claim 19, wherein the processing gas includes the O₂ gas and an unreactive gas.

23. The plasma ashing method of claim 22, wherein the flow rate of the unreactive gas included in the processing gas occupies 75 to 87.5% of the total flow rate of the O₂ gas and an unreactive gas included in the processing gas.

24. The plasma ashing method of claim 22, wherein the unreactive gas is He gas or Ar gas.

25. The plasma ashing method of claim 19, wherein the low dielectric constant film is made of a material including at least Si, O, C and H.

26. The plasma ashing method of claim 19, wherein the ashing process includes a first ashing process followed by a second ashing process, and the object to be processed is mounted on an electrode to which a first electric power having a first frequency and a second electric power having a second frequency lower than the first frequency are simultaneously applied, wherein, in the first ashing process, at least the first electric power adjusted to a first electric power level is applied to the electrode, and in the second ashing process, at least the first electric power adjusted to a second electric power level higher than the first electric power level is applied to the electrode.

27. The plasma ashing method of claim 26, wherein the first frequency is 100 MHz, and the second frequency is 3.2 MHz.

28. The plasma ashing method of claim 26, wherein the first electric power adjusted to the first electric power level of 0.18 to 0.44 W/cm² is applied to the electrode, and the first electric power adjusted to the second electric power level of 0.88 to 2.20 W/cm² is applied to the electrode.

29. The plasma ashing method of claim 26, wherein, in the first and the second ashing processes, the second electric power is not applied to the electrode.

30. The plasma ashing method of claim 26, wherein, in the first ashing process, the second electric power is not applied to the electrode, and in the second ashing process, the second electric power is applied to the electrode.

31. The plasma ashing method of claim 30, wherein the second electric power which is smaller than or equal to 0.44 W/cm² is applied to the electrode.

32. The plasma ashing method of claim 26, wherein, in the first ashing process, the second electric power adjusted to a third electric power level is applied to the electrode, and in the second ashing process, the second electric power adjusted to a fourth electric power level higher than the third electric power level is applied to the electrode.

33. The plasma ashing method of claim 32, wherein the second electric power adjusted to the third electric power level of not higher than 0.18 W/cm² is applied to the electrode, and the second electric power adjusted to the fourth electric power level of not higher than 0.44 W/cm² is applied to the electrode.

34. The plasma ashing method of claim 19, wherein, the ashing process includes a first ashing process followed by a second ashing process, wherein, in the first ashing process, the flow rate of the processing gas is controlled to range from 100 to 800 sccm, and in the second ashing process, the flow rate of the processing gas is controlled to range from 100 to 800 sccm.
